(19) United States
(12) Patent Application Publication
(10) Pub. No.: US 2018/0175296 A1
(43) Pub. Date: Jun. 21, 2018

(54) VAPOR DEPOSITION DEVICE AND VAPOR DEPOSITION METHOD

(71) Applicant: Sharp Kabushiki Kaisha, Sakai City, Osaka (JP)

(72) Inventors: Yuhki KOBAYASHI, Sakai City (JP); Shinichi KAWATO, Sakai City (JP); Manabu NIBOSHI, Sakai City (JP); Satoshi INOUE, Sakai City (JP)

(21) Appl. No.: 15/575,430

(22) PCT Filed: Jun. 28, 2016
(86) PCT No.: PCT/JP2016/069153

§ 371 Date: Nov. 20, 2017

(30) Foreign Application Priority Data
Jul. 3, 2015 (JP) 2015-134630

(51) Int. Cl. H01L 51/00; C23C 14/04; C23C 14/24; H01L 51/56

(52) U.S. Cl. CPC H01L 51/0011; C23C 14/042; H01L 51/56; H01L 51/001; C23C 14/24

(57) ABSTRACT

A vapor deposition device (100) includes a vapor deposition source (30), a vapor deposition mask (10), a limiting plate unit (20), and a gas supply mechanism (50). The limiting plate unit (20) is disposed between the vapor deposition source and the vapor deposition mask. The gas supply mechanism (50) causes a gas wall (501) to be formed in a non-opening portion (13). The non-opening portion (13) is a portion between the vapor deposition mask and the limiting plate unit. The non-opening portion (13) is positioned between limiting-plate openings (21) of the limiting plate unit, which are adjacent to each other, and is positioned between mask opening regions (11) of the vapor deposition mask, which are adjacent to each other in plan view.

### TECHNICAL FIELD

The present invention relates to a vapor deposition device and a vapor deposition method in which a vapor deposition film having a predetermined pattern is formed in a film forming target region on a film forming target substrate having a plurality of film forming target regions.

### BACKGROUND ART

Recently, a flat panel display is utilized in various products or fields, and an increase in size, improved image quality, and reduced consumed power of the flat panel display is required.

Under such circumstances, an EL display device which includes an EL element using electroluminescence (described as “EL” below) of an organic material or an inorganic material is highly attracted as a flat panel display which is an all-solid type and is excellent in a point of low-voltage driving, high-speed responsiveness, self-luminous properties, and the like.

For example, in a case of an active matrix type, the EL display device has a configuration in which an EL element having a thin film shape is provided on a substrate which is configured with a glass substrate or the like and has the TFT (thin film transistor) provided thereon, so as to cause the EL element to be electrically connected to the TFT.

Generally, a full color EL display device is formed such that EL elements which respectively correspond to colors of red (R), green (G), and blue (B) are arranged as sub pixels on a substrate. The full color EL display device displays an image by using the TFT, in a manner that the EL elements selectively emit light at desired luminance by using the TFT.

Thus, in order to manufacture such an EL display device, it is necessary that at least a light-emitting layer configured with a light-emitting material which emits light of each color is formed for each EL element so as to have a predetermined pattern.

When a pattern of the light-emitting layer is formed, for example, a vacuum evaporation method is used. In the vacuum evaporation method, a vapor deposition particle is deposited on a film forming target substrate through a vapor deposition mask which has a predetermined pattern and has openings formed therein. At this time, vapor deposition is performed for each color of the light-emitting layer (this is referred to as “separate application deposition”).

Regarding the vacuum evaporation method, a method in which deposition is performed in a state where a vapor deposition mask having a size which is equal to that of a film forming target substrate is adhered to the film forming target substrate is generally used. However, in this case, the size of the vapor deposition mask is also increased in accordance with an increase in size of the film forming target substrate.

If the size of the vapor deposition mask is increased, a gap is easily formed between the film forming target substrate and the vapor deposition mask by self-weight deflection or elongation of the vapor deposition mask. Therefore, it is difficult to perform patterning in a large-size film forming target substrate, with high precision. In addition, if the size of the film forming target substrate is increased, it is difficult to handle the vapor deposition mask, a frame, or the like. Thus, problems may occur in terms of productivity or safety. Since the vapor deposition device itself or a device attached thereto similarly has an increased size or is complicated, device design is difficult and installation cost is also expensive.

Therefore, in a mass production process, a scan vapor deposition method using a vapor deposition mask which is smaller than a film forming target substrate is more effective than a method of adhering a vapor deposition mask to the entire surface of a film forming target substrate as described above. Since the scan vapor deposition method is used, it is possible to solve the above-described problems which are specific to a case using a large-size vapor deposition mask.

However, in the scan vapor deposition method, a plurality of vapor-deposition source openings (emission ports) for emitting vapor deposition particles are provided in a vapor deposition source so as to be arranged at a constant pitch in a direction perpendicular to a scanning direction, and vapor deposition is performed on the entire surface of a film forming target substrate while scanning is performed in a state where the film forming target substrate and a vapor deposition mask are separated from each other.

Therefore, it is important to control a flow (vapor deposition flow) of vapor deposition particles, in order to perform vapor deposition of a pattern with high precision, and a proposal as measures for this is also provided.

For example, in PTL 1, a shielding wall assembly is provided on one side of a vapor deposition source, and thus a vapor deposition range is restricted by shielding walls. The shielding wall assembly includes a plurality of the shielding walls as a limiting plate. The shielding walls are used for partitioning a space between the vapor deposition source and a vapor deposition mask, into a plurality of vapor deposition spaces. Thus, it is possible to perform vapor deposition of a pattern with high precision without expansion of the vapor deposition pattern.

### CITATION LIST

### Patent Literature

PTL 1: Japanese Unexamined Patent Application Publication No. 2010-270396 (published on Dec. 2, 2010)

PTL 2: Japanese Unexamined Patent Application Publication No. 2005-226154 (published on Aug. 25, 2005)

PTL 3: Japanese Unexamined Patent Application Publication No. 2005-203248 (published on Jul. 28, 2005).

### SUMMARY OF INVENTION

### Technical Problem

Meanwhile, if vapor deposition density is increased (that is, at a time of a high rate), it is difficult to perform vapor deposition of a pattern with high precision, only by using a limiting plate.

In particular, for example, in a case where a plurality of film forming target regions are provided in one film forming target substrate for mass production and the like, it is necessary that vapor deposition particles from a vapor-deposition source opening (adjacent nozzle) for emitting vapor deposition particles to a film forming target region (adjacent film forming target region) adjacent to a certain film forming target region do not fly to this film forming target region corresponding to a certain vapor-deposition source opening on a film forming target surface of the film forming target substrate.

It is not possible to prevent flying of vapor deposition particles from the adjacent nozzle at a time of a high rate, only by using the limiting plate as in PTL 1. This will be specifically described below with reference to FIGS. 15(a) and 15(b).

FIGS. 15(a) and 15(b) are schematic diagrams illustrating a difference of a vapor deposition flow depending on a difference of vapor deposition density in a case where a plurality of limiting plates 621 are provided between a vapor deposition source 601 and a vapor deposition mask 611 in a direction perpendicular to a scanning direction, in plan view.

FIG. 15(a) illustrates a case (time of a low rate) where the vapor deposition density is relatively low. FIG. 15(b) illustrates a case (time of a high rate) where the vapor deposition density is relatively high.

In FIGS. 15(a) and 15(b), a Y axis indicates a horizontal axis along a scanning direction of a film forming target substrate 200, an X axis indicates a horizontal axis along a direction perpendicular to the scanning direction of the film forming target substrate 200, and a Z axis indicates a vertical axis (up and down axis) of a direction which is a normal direction of a film forming target surface 201 of the film forming target substrate 200, is a direction obtained by extending a vapor deposition axis line which is orthogonal to the film forming target surface 201, and is perpendicular to the X axis and the Y axis.

As illustrated in FIG. 15(a), if deposition is performed at a low rate, among vapor deposition particles 301 emitted from each vapor-deposition source opening (emission port, nozzle) 602 of a vapor deposition source 601, vapor deposition components having poor directivity are blocked (captured) by a limiting-plate opening 622 between limiting plates 621, and thus restriction to distribution for high directivity is performed. As a result, a vapor deposition film 300 having a predetermined pattern is formed in a region correlated with each vapor-deposition source opening 602.

However, as illustrated in FIG. 15(b), at the time of a high rate, the vapor deposition particles 601 from the adjacent vapor-deposition source opening 602 fly. Thus, the vapor deposition particles 601 are mixed in the vapor deposition film 300 having a normal pattern (normal patterned film) or a vapor deposition film 302 having an abnormal pattern (abnormal patterned film) is formed between vapor deposition films 300 having a normal pattern.

The reason is as follows. The number of vapor deposition particles 301 in the vapor deposition source 601 at the time of a high rate is increased. However, an opening portion except for the vapor-deposition source opening 602 for forming a film is not provided in the vapor deposition source 601. Therefore, vapor deposition density is locally increased at the vapor-deposition source opening 602, and pressure is increased. As a result, in the vapor-deposition source opening 602 having a small opening area, vapor deposition particles 301 obtained by the reduced mean free process are easily scattered, and the vapor-deposition source opening 602 is apparently expanded (in a pseudo manner), as indicated by a two-dot chain line in FIG. 15(b). The vapor deposition particles 301 which have flied from a place in which the vapor-deposition source opening 602 is expanded in a pseudo manner pass through the limiting-plate opening 622, and then pass through a mask opening 612 corresponding to the adjacent nozzle. Thus, the vapor deposition particles 301 from the adjacent vapor-deposition source opening 602 are mixed in the normal patterned film or the vapor deposition film 302 having an abnormal pattern is formed. Such a phenomenon causes abnormal light emission such as color-mixed light emission, and display quality may be largely impaired.

PTLs 2 and 3 disclose that an introduction portion for a gas is provided in the vapor deposition source or around the vapor deposition source, a flow of the gas (gas flow) is formed in a direction directed from the surrounding of the vapor deposition source toward the film forming target substrate, and this gas flow causes vapor deposition particles emitted from the vapor deposition source to be guided to the film forming target substrate.

However, in PTLs 2 and 3, a flow path of a gas is provided around the vapor deposition source or at the center portion of the vapor deposition source, but a plurality of film forming target regions are not provided in one film forming target substrate and forming a vapor deposition film having an abnormal pattern (that is, abnormal film forming) into the adjacent film forming target region is not prevented.

As described above, abnormal film forming occurs by expansion of the vapor-deposition source opening 602 in a pseudo manner, which is caused by an increase in pressure at the vapor-deposition source opening. However, in PTLs 2 and 3, in a case of a high rate, a vapor deposition flow is guided or hindered from the vicinity of the vapor-deposition source opening at which the vapor deposition density is high. Thus, it is necessary that a large amount of the gas is discharged. Therefore, pressure is more increased at or near the vicinity of the vapor-deposition source opening. Accordingly, in the technologies disclosed in PTLs 2 and 3, it is not possible to prevent an occurrence of the abnormal film forming.

In addition, in the technologies disclosed in PTLs 2 and 3, in a case of a high rate, pressure at or near the vicinity of the vapor-deposition source opening is further increased, and thus vapor deposition at a high rate may be not possible.

Considering the above problems, an object of the present invention is to provide a vapor deposition device and a vapor deposition method in which vapor deposition at a high rate is possible and it is possible to prevent the occurrence of the abnormal film forming.

### Solution to Problem

To solve the above problems, according to an aspect of the present invention, a vapor deposition device forms a vapor deposition film having a plurality of predetermined patterns, in a plurality of film forming target regions of a film forming target substrate. The film forming target substrate includes the plurality of film forming target regions in a first direction and the predetermined patterns are arranged in the first direction. The vapor deposition device includes a vapor deposition source, a vapor deposition mask, a first limiting plate unit, and a gas supply mechanism. The vapor deposition source includes a plurality of vapor-deposition source openings for emitting vapor deposition particles. The vapor deposition mask includes a mask opening region which faces each of the plurality of film forming target regions and includes a plurality of mask openings. The plurality of mask openings are arranged in the first direction so as to correspond to the patterns of the vapor deposition film. The first limiting plate unit is disposed between the vapor deposition source and the vapor deposition mask. The first limiting plate unit includes a plurality of first limiting plates which are disposed to be separated from each other in the first direction. A first limiting-plate opening for causing the vapor deposition particles to pass therethrough is provided between the first limiting plates which are adjacent to each other, so as to correspond to each of the film forming target regions. The gas supply mechanism causes a gas wall to be formed between a non-opening region and the first limiting plate. The non-opening region is positioned between mask opening regions which are adjacent to each other in the vapor deposition mask.

To solve the above problem, according to another aspect of the present invention, a vapor deposition method is used for forming a vapor deposition film having a plurality of predetermined patterns, in a plurality of film forming target regions of a film forming target substrate. The film forming target substrate includes the plurality of film forming target regions in a first direction. The predetermined patterns are arranged in the first direction. The vapor deposition method includes disposing a first limiting plate unit between a vapor deposition source and a vapor deposition mask, the vapor deposition source having a plurality of vapor-deposition source openings for emitting vapor deposition particles, the vapor deposition mask having a mask opening region provided to have a plurality of mask openings arranged in the first direction, the mask opening region being provided to face each of the plurality of film forming target regions, the mask openings corresponding to the patterns of the vapor deposition film, the first limiting plate unit having a plurality of first limiting plates provided to be separated from each other in the first direction, the first limiting plate unit having a first limiting-plate opening provided between the first limiting plates adjacent to each other, the first limiting-plate opening causing the vapor deposition particles to pass therethrough and corresponding to each of the film forming target regions; and emitting the vapor deposition particles from the vapor deposition source and forming the vapor deposition film in a manner that a gas wall is formed between a non-opening region (positioned between mask opening regions which are adjacent to each other in the vapor deposition mask) and the first limiting plate.

### Advantageous Effects of Invention

According to the aspect of the present invention, it is possible to provide a vapor deposition device and a vapor deposition method in which vapor deposition at a high rate is possible and it is possible to prevent the occurrence of abnormal film forming.

### BRIEF DESCRIPTION OF DRAWINGS

FIG. 1 is a sectional view illustrating a basic configuration of a vapor deposition device according to Embodiment 1 of the present invention.

FIG. 2 is a perspective view illustrating the basic configuration of the vapor deposition device according to Embodiment 1 of the present invention.

FIG. 3 is a sectional view illustrating an example of a schematic configuration of the vapor deposition device according to Embodiment 1 of the present invention.

FIG. 4 is a sectional view illustrating a basic configuration of a vapor deposition device according to a modification example of Embodiment 1 of the present invention.

FIG. 5 is a sectional view illustrating a basic configuration of a vapor deposition device according to Embodiment 2 of the present invention.

FIG. 6(a) is a perspective view illustrating a basic configuration of a vapor deposition device according to Embodiment 3 of the present invention, and FIG. 6(b) is a plan view illustrating a schematic configuration of the main components of the vapor deposition device illustrated in FIG. 6(a).

FIG. 7(a) is a perspective view illustrating a basic configuration of a vapor deposition device according to Embodiment 4 of the present invention, and FIG. 7(b) is a plan view illustrating a schematic configuration of the main components of the vapor deposition device illustrated in FIG. 7(a).

FIG. 8 is a sectional view illustrating a basic configuration of a vapor deposition device according to Embodiment 5 of the present invention.

FIG. 9 is a sectional view illustrating a basic configuration of a vapor deposition device according to Embodiment 6 of the present invention.

FIG. 10 is a sectional view illustrating a basic configuration of a vapor deposition device according to Embodiment 7 of the present invention.

FIG. 11 is a sectional view illustrating a basic configuration of a vapor deposition device according to Embodiment 8 of the present invention.

FIG. 12(a) is a sectional view illustrating a basic configuration of a vapor deposition device according to Embodiment 9 of the present invention, and FIG. 12(b) is a bottom view illustrating a schematic configuration of a vapor deposition mask provided with an evacuation mechanism illustrated in FIG. 12(a).

FIG. 13 is a sectional view illustrating a basic configuration of a vapor deposition device according to Embodiment 10 of the present invention.

FIG. 14 is a sectional view illustrating a basic configuration of a vapor deposition device according to Embodiment 11 of the present invention.

FIGS. 15(a) and 15(b) are schematic diagrams illustrating a difference of a vapor deposition flow depending on a difference of vapor deposition density, in a case where a plurality of limiting plates are provided between a vapor deposition source and a vapor deposition mask in a direction perpendicular to a scanning direction, in plan view.

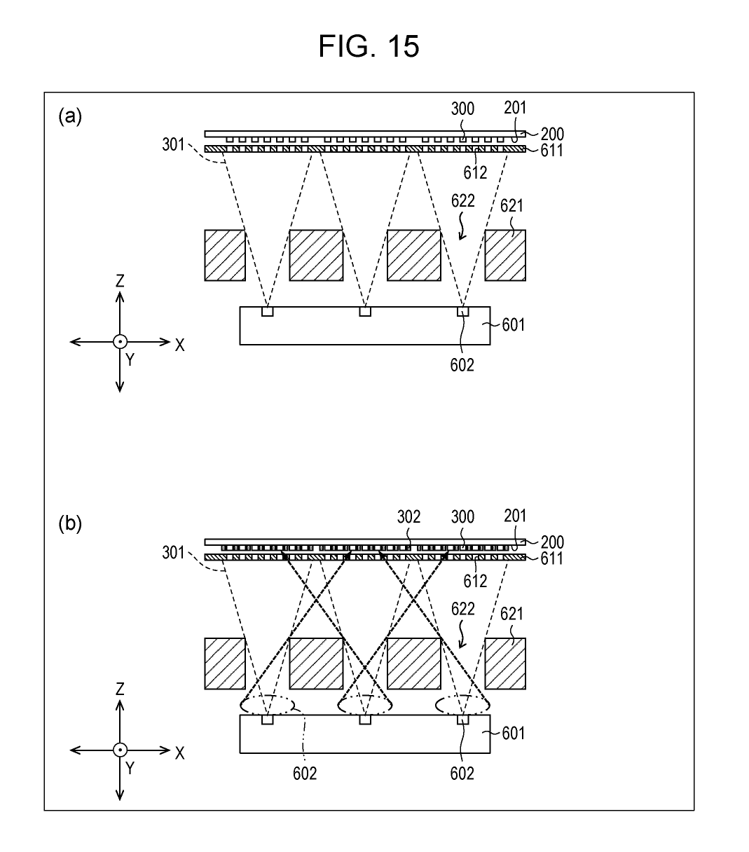

### DESCRIPTION OF EMBODIMENTS

Hereinafter, an example of an embodiment of the present invention will be described in detail.

### Embodiment 1

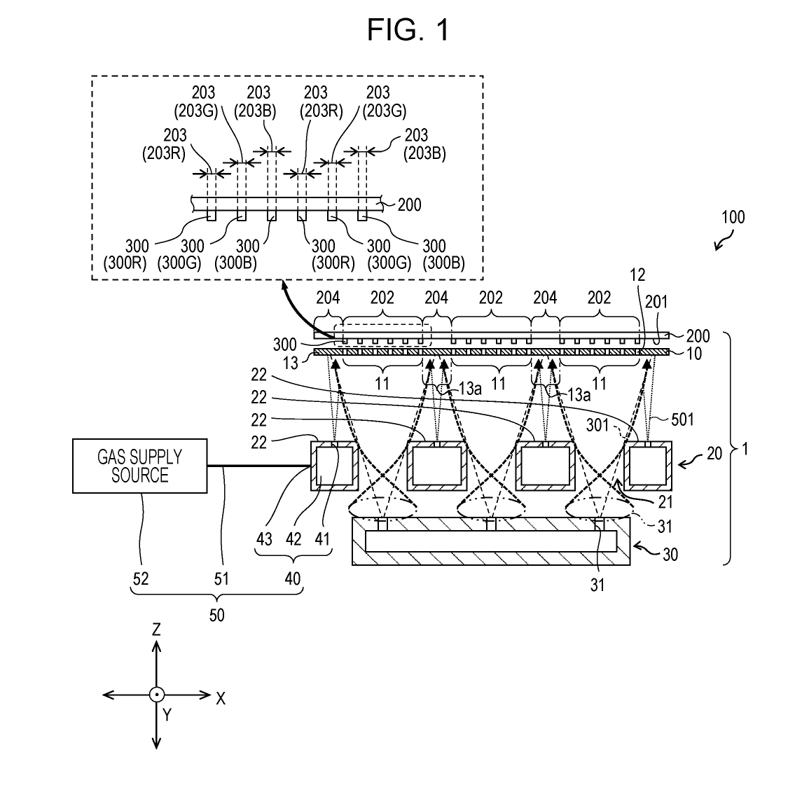

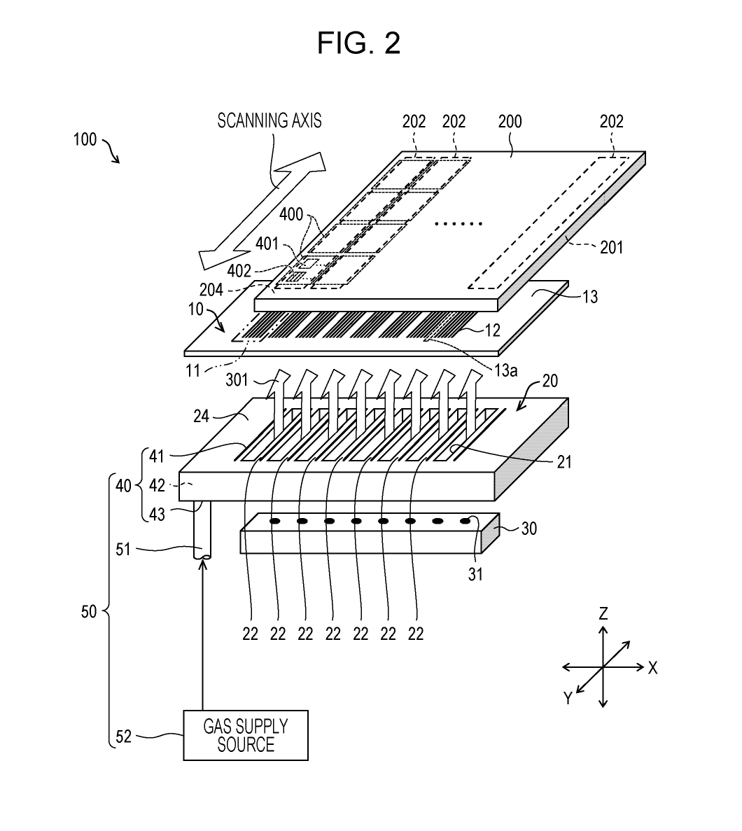

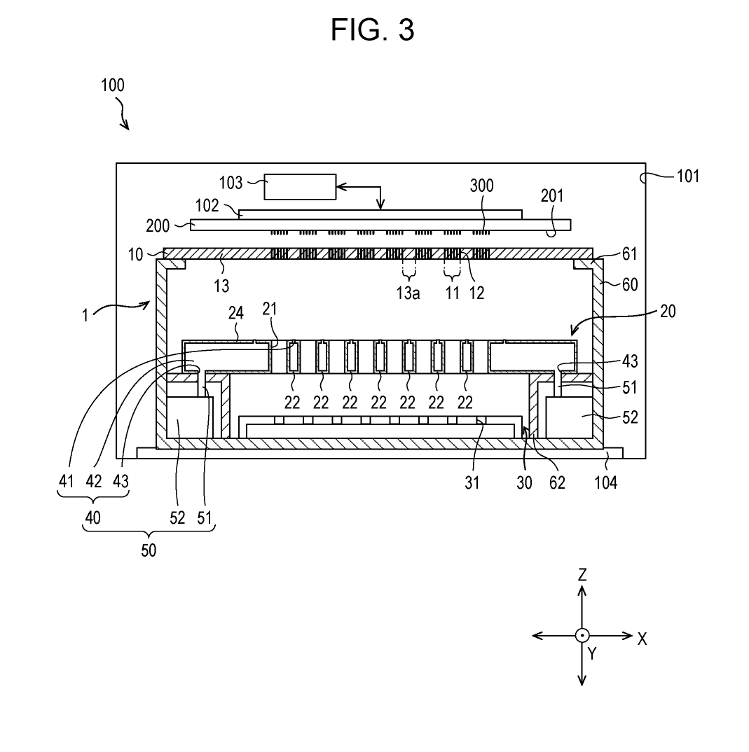

FIG. 1 is a sectional view illustrating a basic configuration of a vapor deposition device 100 according to Embodiment 1 of the present invention. FIG. 2 is a perspective view illustrating the basic configuration of the vapor deposition device 100 according to the embodiment. FIG. 3 is a sectional view illustrating an example of a schematic configuration of the vapor deposition device 100 according to the embodiment.

The vapor deposition device 100 and a vapor deposition method according to the embodiment are particularly useful for vapor deposition of an EL layer such as a light-emitting layer constituting an EL element, in an EL display device such as organic EL display device.

In the following descriptions, as an example, a case where the vapor deposition device 100 and the vapor deposition method according to the embodiment are applied when, for example, an organic EL display device in which organic EL elements of colors of red (R), green (G), and blue (B) are arranged as sub pixels on a substrate so as to perform RGB full-color display, and a light-emitting layer of an organic EL element is formed by an RGB separation application method is manufactured will be described.

That is, in the following descriptions, a case where a vapor deposition film 300 formed by the vapor deposition device 100 according to the embodiment is used as a light-emitting layer of each of colors of R, G, and B in an organic EL display device will be described as an example. However, the embodiment is not limited thereto. The vapor deposition device 100 and the vapor deposition method according to the embodiment may be generally applied to manufacturing of a device, which uses a vapor growth technology, in addition to manufacturing of an organic EL display device and an inorganic EL display device.

As illustrated in FIG. 1, in the embodiment, in an organic EL display device, vapor deposition films 300 constituting a light-emitting layer of each of the colors of R, G, and B are described as a vapor deposition film 300R, a vapor deposition film 300G, and a vapor deposition film 300B in this order. However, in a case where there is no need to particularly distinguish the vapor deposition films 300R, 300G, and 300B for the colors from each other, the vapor deposition films 300R, 300G, and 300B are collectively and simply described as the vapor deposition film 300.

The following descriptions will be made on the assumption that a horizontal axis along a scanning direction (scanning axis) of a film forming target substrate 200 is set as a Y axis, a horizontal axis along a direction perpendicular to the scanning direction of the film forming target substrate 200 is set as an X axis, and a vertical direction (up and down direction) which is a normal direction of a film forming target surface 201 of the film forming target substrate 200 and is perpendicular to the X axis and the Y axis is set as an Z axis. An X-axis direction is set as a row direction (first direction) and a Y-axis direction is set as a column direction (second direction). For convenient descriptions, if particular statements are not made, descriptions will be made on the assumption that a side indicated by an upward arrow in the Z axis is set as an upper (side) in FIG. 1.

<Schematic Configuration of Vapor Deposition Device 100>

(Basic Configuration of Vapor Deposition Device 100)

Firstly, a basic configuration of the vapor deposition device 100 according to the embodiment will be described.

As illustrated in FIGS. 1 to 3, the vapor deposition device 100 according to the embodiment includes a vapor deposition mask 10, a limiting plate unit (first limiting plate unit) 20, a vapor deposition source 30, and a gas supply mechanism 50.

The gas supply mechanism 50 includes a gas injection unit (gas injection unit) 40, a gas supply tube 51, and a gas supply source 52. The gas injection unit 40 has a gas injection port (opening for a gas) 41 which is used for injecting a gas.

In the vapor deposition device 100 according to the embodiment, the limiting plate unit 20 and the gas injection unit 40 are integrated as a limiting plate-gas supply unit, and the gas injection unit 40 is provided in the limiting plate unit 20. The gas injection unit 40 includes a gas injection port 41, a gas diffusion chamber 42, and a gas introduction port 43.

Therefore, the gas supply tube 51 is connected to the limiting plate unit 20. The gas supply tube 51 is connected to the gas supply source 52 that supplies a gas. The configuration of the components in the gas supply mechanism 50 will be described later in detail.

The vapor deposition mask 10, the limiting plate unit 20, and the vapor deposition source 30 are disposed from the film forming target substrate 200 side in a Z-axis direction in this order. The vapor deposition mask 10, the limiting plate unit 20, and the vapor deposition source 30 are disposed to be separated from each other at a predetermined distance and to face each other. The positional relationship between the vapor deposition mask 10, the limiting plate unit 20, and the vapor deposition source 30 is fixed.

The vapor deposition mask 10, the limiting plate unit 20, and the vapor deposition source 30 may be fixed to each other by rigid members, or may have an independent configuration so as to cause a control operation to be performed as one unit.

The vapor deposition device 100 includes a vapor deposition device which performs vapor deposition by a scan vapor deposition method. In the vapor deposition device 100, at least one of the film forming target substrate 200 and a vapor deposition unit 1 is relatively moved (scanned) in the scanning direction, in a state where a constant gap is provided between the vapor deposition mask 10 and the film forming target substrate 200. Thus, finally, the vapor deposition film 300 is formed in the entirety of a film forming target region 202 in the film forming target substrate 200.

(Overall Configuration of Vapor Deposition Device 100)

Next, an example of an overall configuration of the vapor deposition device 100 according to the embodiment will be described below with reference to FIG. 3.

A case where the vapor deposition mask 10, the limiting plate unit 20, the vapor deposition source 30, and the gas supply source 52 connected to the limiting plate unit 20 through the gas supply tube 51 are held by the same holder (holding member) 60, and thus are assembled as a form of the vapor deposition unit 1 will be described below, as an example.

The embodiment is not limited thereto. The gas supply source 52 may be provided on the outside of the holder 60. The gas supply source 52 may be fixed to the outer portion of the holder 60 in a film forming chamber 101 by using a gas supply tube having flexibility as the gas supply tube 51. The gas supply source 52 may be disposed on the outside of the film forming chamber 101.

As illustrated in FIG. 3, the vapor deposition device 100 according to the embodiment includes, for example, a film forming chamber 101, a substrate holder 102, a substrate moving device 103, the vapor deposition unit 1, a vapor-deposition-unit moving device 104, an adhesion prevention plate, a shutter, and a control device. The adhesion prevention plate, the shutter, and the control device are not illustrated in FIG. 3.

The vapor deposition unit 1 includes the vapor deposition mask 10, the limiting plate unit 20, the vapor deposition source 30, the gas supply tube 51, the gas supply source 52, and the holder 60.

(Film Forming Chamber 101)

A vacuum pump (not illustrated) is provided in the film forming chamber 101. The vacuum pump is provided in order to hold the inside of the film forming chamber 101 to be in a vacuum state during vapor deposition. The vacuum pump performs vacuum evacuation of the inside of the film forming chamber 101 through an evacuation port (not illustrated) which is provided in the film forming chamber 101. The vacuum pump is provided on the outside of the film forming chamber 101. The control device that controls an operation of the vapor deposition device 100 is also provided on the outside of the film forming chamber 101. The substrate holder 102, the substrate moving device 103, the vapor deposition unit 1, the vapor-deposition-unit moving device 104, the adhesion prevention plate or the shutter (not illustrated) are provided in the film forming chamber 101.

(Substrate Holder 102)

The substrate holder 102 is a substrate holding member that holds the film forming target substrate 200. The film forming target substrate 200 is held by the substrate holder 102 such that the film forming target surface 201 is disposed to be separated from the vapor deposition mask 10 at a predetermined distance and to face the vapor deposition mask 10.

Preferably, for example, an electrostatic chuck is used as the substrate holder 102. Since the film forming target substrate 200 is fixed to the substrate holder 102 by a method using an electrostatic chuck or the like, the film forming target substrate 200 is held to the substrate holder 102, in a state of being not deflected by the weight of the film forming target substrate.

(Substrate Moving Device 103 and Vapor-Deposition-Unit Moving Device 104)

The vapor deposition device 100 according to the embodiment includes at least one of the substrate moving device 103 and the vapor-deposition-unit moving device 104, for example. Thus, in the embodiment, scan vapor deposition is performed while the film forming target substrate 200 and the vapor deposition unit 1 are relatively moved in the Y-axis direction as the scanning direction by at least one of the substrate moving device 103 and the vapor-deposition-unit moving device 104.

The substrate moving device 103 and the vapor-deposition-unit moving device 104 are not particularly limited. For example, well-known various moving devices such as a roller type moving device and a hydraulic type moving device may be used.

At least one of the film forming target substrate 200 and the vapor deposition unit 1 may be provided to be relatively movable. Thus, only any one of the substrate moving device 103 and the vapor-deposition-unit moving device 104 may be provided, and one of the film forming target substrate 200 and the vapor deposition unit 1 may be fixed to an inner wall of the film forming chamber 101.

(Film Forming Target Substrate 200)

Ahead of descriptions of the vapor deposition mask 10, the film forming target substrate 200 used in the embodiment will be described.

As illustrated in FIGS. 1 and 2, a plurality of film forming target regions 202 which are obtained as vapor-deposition-film patterning regions by partitioning are provided in the film forming target surface 201 of the film forming target substrate 200.

The film forming target substrate 200 refers to a mother substrate. In the mass production process, a plurality of organic EL display devices 400 are formed on a mother substrate, and then the substrate is divided into the organic EL display devices 400.

Each of the film forming target regions 202 is formed to have a stripe shape from one end of the film forming target substrate 200 to the other end. A non-film forming region 204 is provided around each of the film forming target regions 202, so as to surround each of the film forming target regions 202.

A plurality of pixel regions are formed in each of the film forming target regions 202. A plurality of pixels 401 are arranged in each of the pixel regions in each of the organic EL display devices 400. Thus, pixel regions in each of the organic EL display devices 400 are formed in the film forming target substrate 200 so as to have a two-dimensional shape (matrix shape).

Each of the pixels 401 in each of the pixel regions includes sub pixels 402 for colors of R, G, and B. Therefore, a plurality of sub pixels 402 for the colors, which are configured by organic EL elements for the colors of R, G, and B are provided in each of the film forming target regions 202. A fine vapor-deposition-film pattern configured by the vapor deposition films 300R, 300G, and 300B which are used as light-emitting layers of an organic EL element is formed as the vapor deposition film 300 in each of the sub pixels 402.

Although not illustrated, in the embodiment, a driving circuit of the organic EL display device 400 and one electrode of a pair of electrodes which interpose the light-emitting layer in an organic EL element are previously formed in each of the film forming target regions 202.

As illustrated in FIG. 1, target film forming pattern regions 203R, 203G, and 203B are formed in each of the film forming target regions 202, in correspondence with each of the sub pixels. The target film forming pattern regions 203R, 203G, and 203B are respectively provided for forming a pattern of the vapor deposition films 300R, 300G, and 300B for the colors.

A vapor deposition film 300R for the red color is formed in the target film forming pattern region 203R. A vapor deposition film 300G for the green color is formed in the target film forming pattern region 203G. A vapor deposition film 300B for the blue color is formed in the target film forming pattern region 203B. In a case where there is no need to particularly distinguish the target film forming pattern regions 203R, 203G, and 203B for the colors from each other, the target film forming pattern regions 203R, 203G, and 203B are collectively and simply described as a target film forming pattern region 203.

(Vapor Deposition Mask 10)

As illustrated in FIG. 2, the vapor deposition mask 10 is a plate in which a mask surface as the main surface thereof is parallel to an XY plane. In a case where scan vapor deposition is performed, a vapor deposition mask having a size Y-axis direction, which is smaller than that of the film forming target substrate 200 in plan view is used as the vapor deposition mask 10. The plan view means “a case when being viewed from a direction (that is, a direction parallel to the Z axis) perpendicular to the main surface of the vapor deposition mask 10”.

The vapor deposition mask 10 may be used itself, or may be fixed to a mask frame (not illustrated) in a state where tension is applied, in order to suppress an occurrence of self-weight deflection. The mask frame is formed to have an appearance of a rectangle shape which is the same as that of the vapor deposition mask 10 or is bigger than that of the vapor deposition mask 10, in plan view.

As illustrated in FIGS. 1 and 2, a plurality of mask opening regions 11 are provided in the main surface of the vapor deposition mask 10. The mask opening region is configured by a mask opening 12 (first mask opening) group which corresponds to a portion of the pattern of each of the vapor deposition films 300R, 300G, and 300B.

That is, as illustrated in FIGS. 1 and 2, the vapor deposition mask 10 includes the plurality of mask opening regions 11 which face the film forming target region 202 of the film forming target substrate 200 when the mask opening regions 11 face the film forming target substrate 200. A plurality of opening portions (penetration ports) are provided as the mask openings 12, in the mask opening region 11. The opening portions function as passing portions which are used for causing vapor deposition particles (vapor deposition material) 301 to pass therethrough during vapor deposition. A region of the vapor deposition mask 10 other than the mask openings 12 refers to a non-opening portion (non-opening region) 13 and functions as a blocking portion for blocking a flow of the vapor deposition particles 301 during the vapor deposition.

Each of the mask openings 12 is provided to correspond to a portion of each of the patterns of the vapor deposition film 300 which is formed by the vapor deposition mask 10 to be used. Thus, the vapor deposition particles 301 do not adhere to the region other than the aimed target film forming pattern region 203 (that is, target film forming pattern region 203 of a color as a target of film forming by the vapor deposition mask 10 to be used) of the film forming target substrate 200.

In a case where the vapor deposition material is used as the material of a light-emitting layer in an organic EL display device as described above, vapor deposition of the light-emitting layer in an organic EL vapor deposition process is performed for each color of the light-emitting layer.

When the vapor deposition film 300R which is a light-emitting layer for the red color is formed, a vapor deposition mask 10 for forming a light-emitting layer for the red color is used. When the vapor deposition film 300G which is a light-emitting layer for the green color is formed, a vapor deposition mask 10 for forming a light-emitting layer for the green color is used. Similarly, when the vapor deposition film 300B which is a light-emitting layer for the blue color is formed, a vapor deposition mask 10 for forming a light-emitting layer for the blue color is used.

The embodiment is not limited thereto. The light-emitting layers (that is, patterns of the vapor deposition films 300R, 300G, and 300B) for the colors may be formed in a manner that the same vapor deposition mask 10 is used and the position of the mask opening 12 is shifted.

For example, if a vapor deposition mask 10 in which the mask openings 12 are provided only at places corresponding to the light-emitting layer for the green color is used, and vapor deposition is performed in a manner that the vapor deposition mask 10 or the film forming target substrate 200 is shifted so as to cause the mask opening 12 to be shifted from the position facing the target film forming pattern region 203G to the position facing the target film forming pattern region 203R, it is possible to perform pattern film forming of the vapor deposition film 302R on the target film forming pattern region 203R. Similarly, if vapor deposition is performed in a manner that the vapor deposition mask 10 or the film forming target substrate 200 is shifted so as to cause the mask opening 12 to face the target film forming pattern region 203B, it is possible to perform pattern film forming of the vapor deposition film 302B on the target film forming pattern region 203B by using the vapor deposition mask 10.

Only vapor deposition particles 301 which have passed through the mask openings 12 reach the film forming target substrate 200, and thus a vapor deposition film 300 having a pattern which corresponds to the mask openings 12 is formed on the film forming target substrate 200.

For convenient descriptions, FIGS. 1 to 3 are illustrated in a state where the number of mask openings 12, the number of target film forming pattern regions 203, the number of pixels 401, and the like are reduced. In addition, in FIGS. 1 to 3, the mask openings 12 are illustrated without distinguishment between the vapor deposition films 300R, 300G, and 300B from each other.

In the example illustrated in FIG. 2, a plurality of mask openings 12 which have an elongated slit shape extended in the column direction are provided in each of the mask opening regions 11, in the row direction so as to be parallel to each other. At this time, the mask opening 12 may have a slit shape, for example, the number and the shape of mask openings 12 and the mask opening regions 11 in plan view are not particularly limited thereto.

The material of the vapor deposition mask 10 is also not particularly limited. The material of the vapor deposition mask 10 may be metal such as invar (iron-nickel alloy), may be resin or ceramics, or may be used in combination thereof.

(Vapor Deposition Source 30)

The vapor deposition source 30 is a container for accommodating a vapor deposition material, for example. The vapor deposition source 30 may be a container in which the vapor deposition material is directly accommodated, or may be formed to have a load-lock pipe and to cause the vapor deposition material to be supplied from the outside of the vapor deposition source.

As illustrated in FIG. 2, the vapor deposition source 30 is formed to have a rectangular shape, for example. A plurality of vapor-deposition source openings (penetration ports, nozzles) 31 are provided as emission ports for causing vapor deposition particles 301 to be emitted, on the upper surface (that is, a surface which faces the limiting plate-gas supply unit) of the vapor deposition source 30. The vapor-deposition source openings 31 are arranged at a constant pitch in the X-axis direction.

The vapor deposition source 30 generates gaseous vapor deposition particles 301 in a manner that the vapor deposition material is heated so as to be vaporized (in a case where the vapor deposition material is a liquid material) or to be sublimated (in a case where the vapor deposition material is a solid material). The vapor deposition source 30 emits the vapor deposition material which has been gaseous in this manner, from the vapor-deposition source opening 31 to the limiting plate unit 20, as the vapor deposition particles 301.

(Limiting Plate Unit 20)

The limiting plate unit 20 is disposed between the vapor deposition mask 10 and the vapor deposition source 30. The vapor deposition mask 10 and the vapor deposition source 30 are disposed so as to be separated from each other.

In the embodiment, scan vapor deposition is performed in the above-described manner. Thus, any of the vapor deposition mask 10, the limiting plate unit 20, and the vapor deposition source 30 is formed to have at least a size in the Y-axis direction, which is smaller than that of the film forming target substrate 200, in plan view.

The limiting plate unit 20 has a size which is equal to or greater than that of the vapor deposition mask 10 in plan view.

A limiting-plate opening (first limiting-plate opening) 21 and a gas injection port 41 are provided in the limiting plate unit 20. The limiting-plate opening 21 causes vapor deposition particles 301 to pass through. The gas injection port 41 injects a gas supplied from the gas supply source 52.

The vapor deposition particle 301 emitted from the vapor-deposition source opening 31 is diffused substantially isotropically. The limiting-plate opening 21 has a function of controlling the flow (vapor deposition flow) of the vapor deposition particles 301 which have been diffused isotropically, and improving directivity.

The gas injection port 41 has a function of blocking an unnecessary vapor deposition flow generated by pseudo spread of the vapor-deposition source openings 31, in a manner that a gas wall (wall of a gas) 501 is formed between the limiting plate unit 20 and the vapor deposition mask 10 by using the flow (gas flow) of a gas.

The gas wall (gas flow) 501 functions as a shielding wall that hinders (blocks) the flow of vapor deposition particles 301 which are directed to a mask opening region (adjacent mask opening region) 11 which is adjacent to the mask opening region 11 which is correlated with the limiting-plate opening 21 and into which the vapor deposition particles are to be originally incident among the vapor deposition particles 301 which have passed through the limiting-plate openings 21. The shielding wall performs blocking by molecular collision. Thus, vapor deposition particles 301 which have passed through each of the limiting-plate openings 21 are directed in a direction toward the mask opening region 11 facing each of the limiting-plate openings 21, by the gas wall 501.

Accordingly, the gas wall 501 functions as a barrier that hinders an occurrence of a situation in which vapor deposition particles 301 which have passed through each of the limiting-plate openings 21 reach the adjacent mask opening region over the gas wall 501. In addition, the gas wall 501 functions as a guide that regulates the flow of the vapor deposition particles 301 which have passed through each of the limiting-plate openings 21 and guides these vapor deposition particles 301 to the mask opening region 11 correlated with each of the limiting-plate opening 21.

The limiting plate unit 20 is a unit having a hollow block shape, for example. The limiting plate unit 20 has a configuration in which a plurality of limiting-plate openings 21 and gas injection ports 41 are provided in a rectangular hollow plate member in which the XY plane is used as the main surface, and the X-axis direction is used as the major axis, so as to be arranged at a constant pitch in the X-axis direction.

The adjacent limiting-plate opening 21 is separated by the limiting plates 22 (first limiting plate, limiting portion, gas injection unit) for restricting movement of vapor deposition particles 301. The limiting plates 22 are separated from each other in plan view, and are arranged at a constant pitch so as to be parallel to each other in the X-axis direction.

The limiting-plate opening 21 is a penetration port provided between the limiting plates 22 which are adjacent to each other in the X-axis direction. The limiting-plate opening 21 is formed by penetrating the limiting plate unit 20 in the Z-axis direction. The opening shape of the limiting-plate opening 21 is a substantially rectangular shape in which the major-axis direction is parallel to the Y axis.

The gas injection port 41 is provided on a surface of each of the limiting plates 22, which faces the vapor deposition mask 10.

The limiting-plate opening 21 and the film forming target region 202 have a one-to-one relationship. Thus, the limiting-plate opening 21 and the mask opening region 11 have a one-to-one relationship.

The pitch between the limiting-plate openings 21 is formed to be greater than the pitch between the mask openings 12. A plurality of mask openings 12 are arranged between the limiting plates 22 which are adjacent to each other in the X-axis direction, in plan view.

The limiting-plate opening 21 and the vapor-deposition source opening 31 are formed to have the same pitch in the X-axis direction. Therefore, the limiting-plate opening 21 and the vapor-deposition source opening 31 have a one-to-one relationship in the X-axis direction. The vapor-deposition source openings 31 are disposed to respectively correspond to the limiting-plate openings 21 such that each of the vapor-deposition source openings 31 is positioned at the central position of each of the limiting-plate openings 21 in the X-axis direction (that is, at the central position between the limiting plates 22 which interpose each of the vapor-deposition source opening 31 in the X-axis direction and are adjacent to each other, in the X-axis direction).

As illustrated in FIG. 2, in the embodiment, a line vapor deposition source is used as the vapor deposition source 30. In the line vapor deposition source, vapor-deposition source openings 31 are arranged in the X-axis direction so as to have a one-dimensional shape (that is, line shape). Therefore, the vapor-deposition source opening 31 is disposed, for example, at the center (center in both directions of the X axis and the Y axis) of each of the limiting-plate openings 21 in plan view. Thus, each of the vapor-deposition source openings 31 has a one-to-one relationship with each of the limiting-plate openings 21.

The embodiment is not limited thereto. The vapor-deposition source openings 31 may be arranged in the X-axis direction and the Y-axis direction so as to have a two-dimensional shape (tile shape). Even in a case where the vapor-deposition source openings 31 are arranged to have a two-dimensional shape, it is desirable that each of the vapor-deposition source openings 31 is disposed to be positioned at the central position of each of the limiting-plate openings 21 in the X-axis direction.

The position of the gas injection port 41 in each of the limiting plates 22 is not limited. The gas injection port 41 may be suitably positioned at the center of the limiting plate 22 in plan view. If the gas injection port 41 is provided at an end of the limiting plate 22, the probability of an inflow (invasion) of a gas injected from the gas injection port 41 into the mask opening region 11 may be increased. Thus, this case may influence element characteristics of an organic EL element, for example, deterioration of light-emitting efficiency or a decrease of a lifespan.

The size of the gas injection port 41 is also not particularly limited. The opening length of the gas injection port 41 in a direction parallel to the scanning direction (described as “a scanning-direction opening length” below) is preferably equal to or longer than the scanning-direction opening length of the limiting-plate opening 21. If the scanning-direction opening length of the gas injection port 41 is shorter than the scanning-direction opening length of the limiting-plate opening 21, a site in which the gas wall 501 exists at a position which is adjacent to the limiting-plate opening 21, and it is not possible to prevent an occurrence of a situation in which vapor deposition particles 301 toward the adjacent mask region are blocked in this site.

The opening length (described as “an opening width” below) of the gas injection port 41 in the direction perpendicular to the scanning direction is preferably about several mm. In a case where the opening width of the gas injection port 41 is large, the amount of a gas flowing into the mask opening region 11 may be increased and this may influence element characteristics. In a case where the opening width of the gas injection port 41 is too small, gas density in the vicinity of the gas injection port 41 may be increased and a gas itself may be largely diffused.

At least a gas introduction port 43 for causing a gas to be introduced into the limiting plate unit 20 is provided in the limiting plate unit 20.

As described above, the limiting plate unit 20 according to the embodiment is hollow and includes a gas diffusion chamber 42 joined to the gas introduction port 43. The gas diffusion chamber 42 is a joining portion for joining the gas introduction port 43 and the gas injection port 41 to each other. The gas diffusion chamber 42 functions as a gas supply path (ventilation path) for diffusing the gas introduced from the gas introduction port 43 and supplying the gas to the gas injection port 41.

A gas supply tube 51 is connected to the gas introduction port 43. As illustrated in FIG. 1, the gas introduced from the gas introduction port 43 to the gas diffusion chamber 42 passes through the gas injection port 41, and is injected from each of the limiting plates 22 to non-opening portions 13 of the vapor deposition mask 10, which interpose each of the mask opening region 11 in the X-axis direction.

(Gas Supply Tube 51 and Gas Supply Source 52)

The gas supply tube 51 is connected to the gas supply source 52 that supplies a gas. The gas supply tube 51 is a joining tube for joining the gas supply source 52 and the limiting plate unit 20 to each other. The gas supply tube 51 function as a gas supply path for supplying a gas from the gas supply source 52 to the limiting plate unit 20.

The gas used in the embodiment may be injected from the gas injection port 41 in a gaseous form, and may not react with the vapor deposition particle 301. An inert gas is suitably used. Among inert gases, a N₂ (nitrogen) gas, an Ar (argon) gas, a He (helium), and the like are preferably used because of low price and easy obtainment.

The flow rate of the gas is not particularly limited. However, since the number of vapor deposition particles 301 functioning as the cause of the occurrence of abnormal film forming varies depending on a vapor deposition rate, the flow rate of the gas may be appropriately controlled in accordance with the vapor deposition rate.

An on-off valve (not illustrated) is provided in the gas supply tube 51. The on-off valve controls a supply of a gas from the gas supply source 52 to the gas introduction port 43 by a control of a control unit (not illustrated).

The on-off valve is not particularly limited. However, for example, an electromagnetic valve is used. In this case, the on-off valve is opened or closed in a manner that the valve body is operated based on a control signal from the control unit (not illustrated), by using magnetism of an electromagnet (solenoid).

The gas supply source 52 may be a gas cylinder for accommodating a gas such as an inert gas or may be a gas generation device that generates a gas.

(Holder 60)

The holder 60 includes a rack 61 and the like. The holder 60 is a holding member that holds the components of the vapor deposition unit 1, such as the vapor deposition mask 10, the limiting plate unit 20, and the vapor deposition source 30.

The configuration of the holder 60 is not particularly limited so long as the holder 60 can hold the vapor deposition mask 10, the limiting plate unit 20, and the vapor deposition source 30 so as to fix relative positions of the vapor deposition mask 10, the limiting plate unit 20, and the vapor deposition source 30.

FIG. 3 illustrates, as an example, a case where vapor deposition (up-deposition) is performed on the film forming target substrate 200 by directing the vapor deposition particles 301 upwardly from the lower part as illustrated in FIG. 1. Therefore, FIG. 3 illustrates an example in which the vapor deposition mask 10, the limiting plate unit 20, and the vapor deposition source 30 are disposed in an order from the film forming target substrate 200 side, which is disposed over the holder 60.

However, for example, in a case where vapor deposition (down-deposition) is performed on the film forming target substrate 200 by directing the vapor deposition particles 301 downward from the upper part, the vapor deposition source 30, the limiting plate unit 20, the vapor deposition mask 10, and the film forming target substrate 200 are disposed in this order from the upper part.

Disposition of the vapor deposition source 30, the limiting plate unit 20, the vapor deposition mask 10, and the film forming target substrate 200 are appropriately changed in accordance with an emission direction of the vapor deposition particles 301.

The holder 60 may include, for example, a tension mechanism (not illustrated) that applies tension to the vapor deposition mask 10, or may further include an adhesion prevention plate (shielding plate), a shutter, or the like which are not illustrated.

In particular, in a case where the gas supply source 52 connected to the limiting plate unit 20 is built in the holder 60, it is preferable that the gas supply source 52 is covered by an adhesion prevention plate 62, in order to prevent an occurrence of a situation in which vapor deposition particles which fly from the vapor-deposition source opening 31 adhere to the gas supply source 52. The adhesion prevention plate 62 may function as a rack.

<Vapor Deposition Method>

In the embodiment, as described above, scan vapor deposition is performed by relatively moving the vapor deposition unit 1 and the film forming target substrate 200.

Therefore, firstly, the vapor deposition mask 10 and the film forming target substrate 200 in the vapor deposition unit 1 are disposed to face each other and to be separated from each other at a predetermined distance. At this time, relative positioning of the vapor deposition mask 10 and the film forming target substrate 200, that is, adjustment of a gap (gap control) between the vapor deposition mask 10 and the film forming target substrate 200 is performed by using an alignment marker (not illustrated) which is provided in each of the vapor deposition mask 10 and the film forming target substrate 200.

Then, while vapor deposition particles 301 are emitted from the vapor-deposition source opening 31 and a gas is injected from the gas injection port 41, at least one of the vapor deposition unit 1 and the film forming target substrate 200 is relatively moved in the scanning direction (that is, Y-axis direction perpendicular to an arrangement direction of the limiting plates 22 and the limiting-plate openings 21) in plan view.

The gas is injected from the gas injection port 41, and thus the gas wall 501 by the injected gas is formed between each of the limiting plates 22 in the limiting plate unit 20 and the non-opening portions 13 of the vapor deposition mask 10, which interpose each of the mask opening region 11 in the X-axis direction.

In the embodiment, vapor deposition particles 301 emitted from the vapor-deposition source opening 31 are deposited on the film forming target substrate 200 through the limiting-plate opening 21 and the mask opening 12 in each of the mask opening region 11 partitioned by the gas wall 501.

### Advantageous Effects

In the embodiment, the vapor deposition flow is controlled by using the limiting-plate opening 21 formed between the limiting plates 22, and thus only a trace amount of an unnecessary component is blocked by the gas wall 501.

The limiting plate unit 20 partitions a space between the vapor deposition mask 10 and the vapor deposition source 30 into a plurality of vapor deposition spaces configured from the limiting-plate openings 21, by using the limiting plates 22. Thus, an angle at which the vapor deposition particles 301 emitted from the vapor deposition source 30 pass therethrough is limited.

If vapor deposition density is increased, the vapor deposition flow is much more spread. Thus, in order to suppress spread of the vapor deposition flow, it is necessary that the spread of the vapor deposition flow is narrowed in three dimensions.

The vapor deposition particles 301 emitted from the vapor deposition source 30 have passed through the limiting-plate openings 21, and then pass through the mask openings 12 formed in the vapor deposition mask 10. Thus, vapor deposition is performed on the film forming target substrate 200.

The limiting plate unit 20 restricts movement of the vapor deposition particles 301 in an arrangement direction (that is, X-axis direction and inclined direction) of the limiting plates 22 by using the limiting plates 22. The limiting plate unit 20 selectively hinders the vapor deposition particles from passing through the limiting-plate openings 21, in accordance with an incident angle of the vapor deposition particles 301 which have been incident to the limiting-plate openings 21.

The gas injection unit 40 blocks the vapor deposition particles 301 (as the cause of the abnormal film forming occurring by pseudo spread of the vapor-deposition source opening 31 at a time of a high rate) by using the gas wall 501 which is formed by a gas injected (emitted) from a surface of the limiting plate 22, which faces the vapor deposition mask 10. Accordingly, the occurrence of the abnormal film forming is prevented.

If the gas wall 501 is formed between the limiting plate 22 and the non-opening portion 13a which is provided between the mask opening region 11 among the non-opening portions 13 in the vapor deposition mask 10, it is possible to hinder an occurrence of a situation in which the vapor deposition particles 301 which have passed through the limiting-plate openings 21 reach the adjacent mask opening region over the gas wall 501.

If the gas wall 501 is formed at the outside portions of both ends of the mask opening region 11 in the vapor deposition mask 10 in the X-axis direction, in addition to the non-opening portion 13a provided between the mask opening regions 11, it is also possible to guide the vapor deposition particles 301 which have passed through the limiting-plate opening 21 correlated with the mask opening region 11, to the mask opening region 11 without waste, regarding both of the ends of the mask opening region 11 in the X-axis direction. Therefore, it is possible to improve utilization efficiency of the vapor deposition material.

Thus, it is desirable that the gas introduced from the gas introduction port 43 to the limiting plate unit 20 is injected to the non-opening portions 13 of the vapor deposition mask 10 which interpose the mask opening region 11 in the X-axis direction, that is, the non-opening portion 13a which is provided between the mask opening regions 11 among the non-opening portions 13 of the vapor deposition mask 10, and to the outside portion of the both ends of the mask opening region 11 in the X-axis direction (that is, a portion of the vapor deposition mask 10, which faces the gas injection port 41 positioned on the X-axis direction edge side, not on the limiting-plate openings 21 side of both ends of the limiting plate unit 20 in the X-axis direction).

As described above, according to the embodiment, it is possible to prevent the occurrence of the abnormal film forming occurring by pseudo spread of the vapor-deposition source opening 31 at the time of a high rate. In the embodiment, the vapor deposition flow is controlled by using the limiting-plate opening 21 formed between the limiting plates 22, and thus only a trace amount of an unnecessary component is blocked by the gas wall 501. Thus, a situation in which pressure in the vicinity of the vapor-deposition source opening 31 is increased does not occur.

In the embodiment, only a trace amount of an unnecessary component may be blocked by the gas wall 501. Thus, the amount of a gas may be small and a situation in which the vacuum degree is significantly decreased does not occur.

The vapor deposition flow for forming the vapor deposition film 300 which is originally obtained by vapor deposition (that is, vapor deposition flow other than an unnecessary vapor deposition flow generated by the pseudo spread of the vapor-deposition source opening 31) passes through the limiting-plate opening 21, and then reaches the vapor deposition mask 10 in a direction itself controlled by the limiting-plate opening 21. Thus, the vapor deposition flow is not directed to the gas wall 501.

Therefore, according to the embodiment, it is possible to provide a vapor deposition device and a vapor deposition method in which vapor deposition at a high rate is possible and it is possible to prevent the occurrence of abnormal film forming even in a case where vapor deposition is performed at the high rate.

A vapor deposition flow is formed between each of the limiting-plate openings 21 and each of the mask opening regions 11. This vapor deposition flow is used for forming the vapor deposition film 300 which is originally obtained by vapor deposition, and has high density of vapor deposition particles 301. Gas density is lower than the density of the vapor deposition flow for forming the vapor deposition film 300 which is originally obtained by vapor deposition. In the embodiment, since the trace amount of an unnecessary component may be blocked by the gas wall 501, the gas injection port 41 is smaller than the vapor-deposition source opening 31, and the amount of a gas is small. In addition, in the embodiment, the scan vapor deposition is performed, and thus the vapor deposition mask 10 is formed to have a length in the Y-axis direction, which is shorter than that of the film forming target substrate 200, and at least one of the film forming target substrate 200 and the vapor deposition unit 1 is relatively moved in the Y-axis direction with respect to the other.

Therefore, the gas sprayed to the non-opening portions 13 which interpose each of the mask opening regions 11 in the X-axis direction is diffused in the Y-axis direction, and is escaped upwardly from the edge of the vapor deposition mask 10 in the Y-axis direction. Thus, according to the embodiment, it is possible to significantly reduce the amount of the gas mixed in the mask opening region 11. Accordingly, according to the embodiment, it is possible to suppress deterioration of the element characteristics.

In a case where the unnecessary component is blocked by using only the limiting plates 22, it is difficult to correspond to various vapor deposition rates by using the same limiting plate unit 20, and thus it is necessary that a limiting plate unit 20 corresponding to a vapor deposition rate is used. However, in the vapor deposition device 100 and the vapor deposition method according to the embodiment, since the unnecessary component is blocked by the gas wall 501, the flow rate of a gas may be adjusted for each vapor deposition rate, and versatility is high.

### Modification Example

(Shape of Limiting Plate Unit 20)

In the embodiment, the limiting plate unit 20 is a unit having a hollow block shape. In the hollow plate-shape member constituting the limiting plate unit 20, a portion (that is, non-opening portion) other than the limiting-plate opening 21 is a holding body portion 24 that is joined to the limiting plate 22 so as to hold the limiting plate 22. A case where the limiting plate unit 20 has a configuration in which a plurality of limiting plates 22 and the holding body portion 24 are integrally formed will be described as an example.

However, the limiting plate unit 20 according to the embodiment is not limited thereto. The limiting plate unit 20 may have a configuration in which the limiting plates 22 which are arranged through the limiting-plate openings 21 are fixed to the frame-like holding body portion 24 which is joined to the limiting plates 22 so as to hold the limiting plates 22, by screw fastening, welding, or the like.

That is, the limiting plates 22, and the limiting plates 22 and the holding body portion 24 may be integrally formed as illustrated in FIG. 2, or may be formed to be separated from each other. A method of holding the limiting plates 22 is not limited to the above method, so long as the relative position or posture of each of the limiting plates 22 can be maintained to be constant. Accordingly, the shape of the limiting plate unit 20 is not particularly limited.

Since the limiting plate unit 20 is formed to have a block shape as illustrated in FIG. 2, the limiting plate unit 20 can be formed to be compact, and positioning of each of the limiting plates 22 or a replacement work of the limiting plate unit 20 is easily performed. Therefore, the limiting plate unit 20 is preferably formed to have a block shape.

(Shape of Gas Injection Port 41)

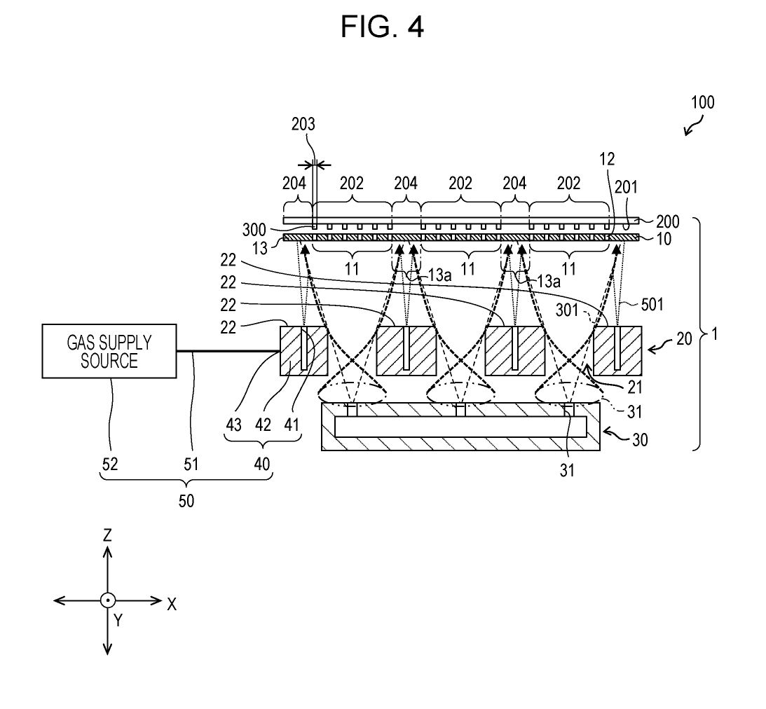

FIG. 4 is a sectional view illustrating a basic configuration of a vapor deposition device 100 according to the modification example.

The depth (nozzle length) of the gas injection port 41 is not limited. However, as the nozzle length of the gas injection port 41 increases, directivity of a gas is improved, and thus it is possible to suppress diffusion of an extra gas. The gas injection port 41 does not penetrate the limiting plate unit 20. Thus, as illustrated in FIG. 4, as the nozzle length of the gas injection port 41 becomes longer in a range without penetrating the limiting plate unit 20, it is more preferable.

Therefore, FIG. 1 illustrates a case where the gas diffusion chamber 42 is provided in the limiting plate 22, as an example. However, the gas diffusion chamber 42 may be provided only at the holding body portion 24.

That is, the vapor deposition device 100 may have a configuration in which, for example, a gas diffusion chamber 42 joined to the gas introduction port 43 is provided in the holding body portion 24 and a gas injection port 41 having a length in the Z-axis direction, which is longer than that in FIG. 1 is provided in the limiting plate 22.

Alternatively, in the vapor deposition device 100, a branch pipe as a ventilation pipe (ventilation path) may be provided in the holding body portion 24, instead of the gas diffusion chamber 42, and the gas introduction port 43 and the gas injection port 41 may be joined to each other by the branch pipe.

In addition, the vapor deposition device 100 may have a configuration in which a plurality of gas introduction ports 43 which respectively correspond to the limiting plates 22 are provided in the limiting plate unit 20, the gas supply tube 51 functions as the branch pipe, and thus a gas is supplied from the gas supply tube 51 to each of the limiting plates 22 through the gas introduction ports 43.

(Vapor Deposition Film 300)

In the embodiment, as an example, a case where the vapor deposition films 300 are light-emitting layers of the colors of R, G, and B in an organic EL display device has been described. However, the organic EL element may include an organic layer (other than the light-emitting layer) between a pair of electrodes.

However, in the embodiment, one electrode of the pair of electrodes may be formed, and then an organic layer other than a light-emitting layer may be formed used as the vapor deposition film 300, by using the vapor deposition device 100, or a light-emitting layer may be formed as the vapor deposition film 300, in each of the film forming target regions 202 of the film forming target substrate 200, on which the one electrode and the organic layer other than the light-emitting layer may be formed.

(Vapor Deposition Method)

In the embodiment, an example, a case where a vapor deposition mask having at least a size in the Y-axis direction, which is smaller than that of the film forming target substrate 200 in plan view is used as the vapor deposition mask 10, and the scan vapor deposition is performed by relatively moving the vapor deposition unit 1 and the film forming target substrate 200.

However, the embodiment is not limited thereto. A vapor deposition mask having the same size as that of the film forming target substrate 200 may be used as the vapor deposition mask 10, and vapor deposition may be performed in a state where the vapor deposition mask 10 and the film forming target substrate 200 are in contact with each other.

In this case, the amount of a gas mixed in the mask opening region 11 is significantly reduced. Thus, as in an embodiment which will be described later, it is preferable that an opening portion as a loophole of a gas is formed in each of the vapor deposition mask 10 and the film forming target substrate 200.

(Scanning-Direction Opening Length of Gas Injection Port 41)

In the embodiment, as an example, a case where the scanning-direction opening length of the gas injection port 41 is equal to or longer than the scanning-direction opening length of the limiting-plate opening 21 is described. However, the embodiment is not limited thereto.

As described above, a gas sprayed to the vapor deposition mask 10 is diffused in the Y-axis direction and flows. Therefore, in a case where the scanning-direction opening length of the gas injection port 41 is equal to or longer than the scanning-direction opening length of the limiting-plate opening 21, if a gas is sprayed in a range which is the same as a range in which a gas is sprayed to the vapor deposition mask 10, the gas injection port 41 may be continuously formed. In other words, the scanning-direction opening length of the gas injection port 41 is not particularly limited so long as a gas is sprayed to the surface of the vapor deposition mask 10, which faces the limiting plate unit 20, so as to form the gas wall 501 along the non-opening portion 13a in the Y-axis direction, without interruption.

### Embodiment 2

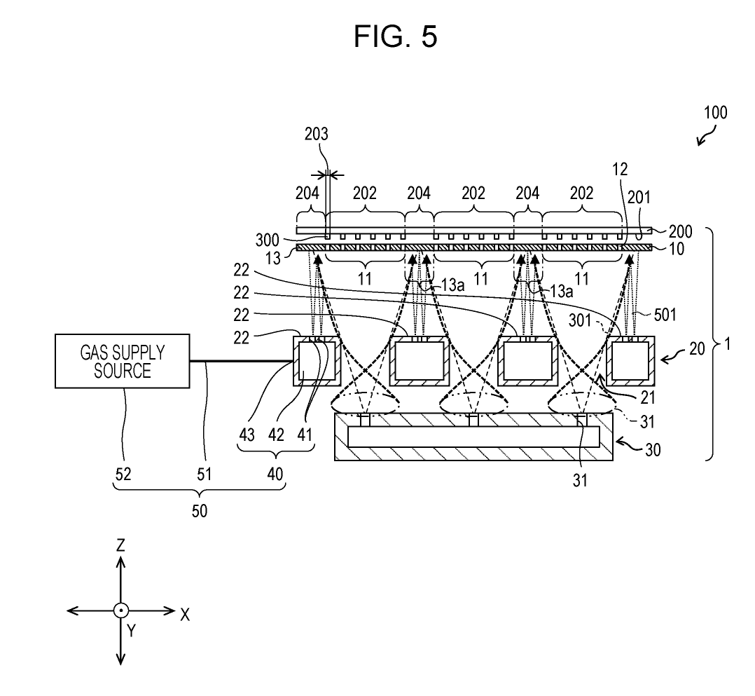

An embodiment will be described with reference to FIG. 5, as follows. In the embodiment, a difference from Embodiment 1 will be described. Components having the same function as the component used in Embodiment 1 are denoted by the same reference signs, and descriptions thereof will be not repeated.

FIG. 5 is a sectional view illustrating a basic configuration of a vapor deposition device 100 according to the embodiment.

The vapor deposition device 100 according to the embodiment is the same as the vapor deposition device 100 according to Embodiment 1 except that a plurality (that is, at least two) of gas walls 501 are formed between each of the limiting plates 22 and the non-opening portion 13a which is provided between the mask opening regions 11 in the vapor deposition mask 10. In FIG. 5, two gas walls 501 are formed between each of the limiting plates 22 and the non-opening portion 13a.

That is, regarding the mask opening regions 11 at both ends of the vapor deposition mask 10, only one mask opening region 11 which is adjacent to each of these mask opening regions 11 in the X-axis direction is provided. Therefore, regarding the mask opening regions 11 at both ends of the vapor deposition mask 10 in the X-axis direction, only vapor deposition particles 301 from the limiting-plate opening 21 which faces a mask opening region 11 adjacent to one side of the above mask opening region 11, toward the mask opening region 11 may be blocked.

However, regarding a mask opening 12 other than the mask opening region 11 at both ends of the vapor deposition mask 10 in the X-axis direction, vapor deposition particles 301 from the limiting-plate openings 21 which face the mask opening regions 11 on both sides of the mask opening region 11, toward the mask opening region 11 may be blocked.

Therefore, since a plurality of gas injection ports 41 are provided in each of the non-opening portions 13a in the X-axis direction, a probability of blocking such vapor deposition particles 301 is increased.

In the embodiment, a plurality (two in the example illustrated in FIG. 2) of gas injection ports 41 are formed in the X-axis direction so as to correspond to one limiting plate 22.

In FIG. 5, two gas injection ports 41 are provided for each of all limiting plates 22, in the X-axis direction. However, as described above, regarding the mask opening regions 11 at both ends of the vapor deposition mask 10 in the X-axis direction, only vapor deposition particles 301 from the limiting-plate opening 21 which faces a mask opening region 11 adjacent to one side of the above mask opening region 11, toward the mask opening region 11 may be blocked.

Therefore, the gas injection port 41 may be provided in the X-axis direction in the non-opening portion 13 on the outside of the mask opening region 11 at both ends of the vapor deposition mask 10 in the X-axis direction, so as to form one gas wall 501. Accordingly, only one gas injection port 41 may be provided on the outside of the limiting-plate opening 21 at both ends of the limiting plate unit 20 in the X-axis direction.

As described above, even in a case where the plurality of gas injection ports 41 are provided in the X-axis direction so as to correspond to one limiting plate 22, it is preferable that the gas injection port 41 is formed at the center portion (vicinity of the center) of the limiting plate 22. If the gas injection ports 41 are close to each other, a gas is diffused in the vicinity of each of the gas injection ports 41. Thus, it is preferable that the gas injection ports 41 are suitably provided to be separated from each other at several mm.

### Embodiment 3

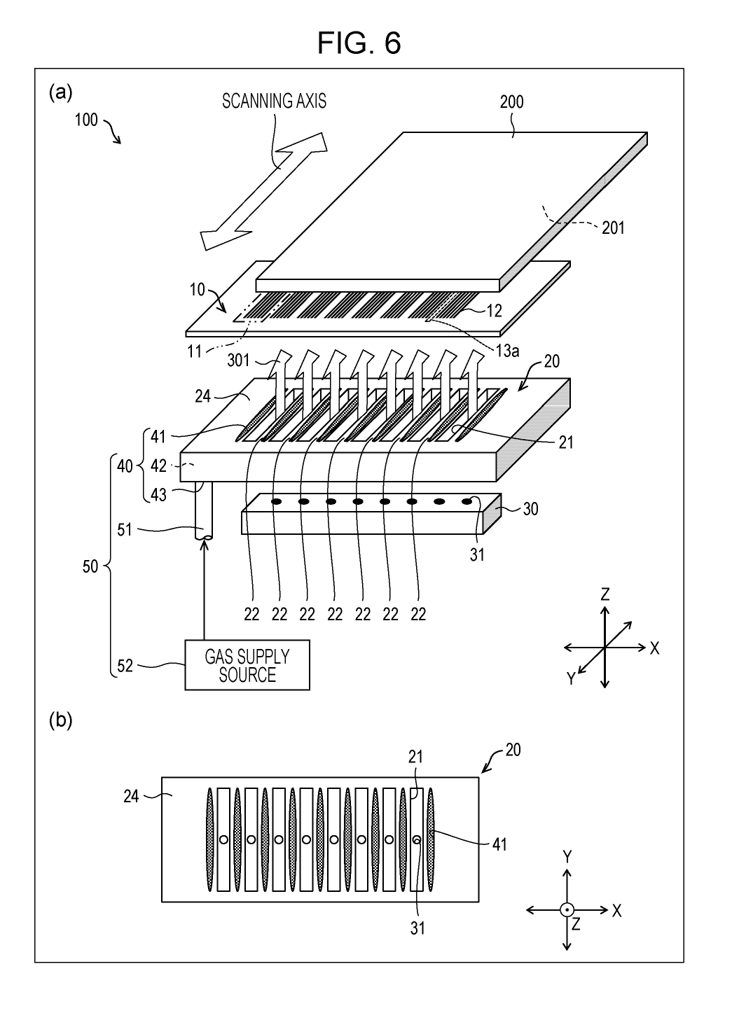

An embodiment will be described with reference to FIG. 6, as follows. In the embodiment, a difference from Embodiments 1 and 2 will be described. Components having the same function as the component used in Embodiments 1 and 2 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiment 2 may be made.

FIG. 6(a) is a perspective view illustrating a basic configuration of a vapor deposition device 100 according to the embodiment. FIG. 6(b) is a plan view illustrating a schematic configuration of the main components of the vapor deposition device 100 illustrated in FIG. 6(a). FIG. 6(b) illustrates a state where the limiting plate unit 20 and the vapor deposition source 30 in the vapor deposition device 100 are viewed from the upper part of the limiting plate unit 20.

FIG. 2 illustrates, as an example, a case where the opening width of the gas injection port 41 (that is, opening length of the gas injection port 41 in the X-axis direction perpendicular to the scanning direction) is normally constant in the Y-axis direction. However, the opening width of the gas injection port 41 may vary depending on the position thereof in the Y-axis direction.

Regarding density of the vapor deposition particles 301 which pass through the limiting-plate openings 21, density at the center portion of the limiting-plate opening 21 in the Y-axis direction, which is next above the limiting-plate opening 21 in plan view is highest. Therefore, regarding the number of vapor deposition particles 301, which acts as the cause of the occurrence of abnormal film forming and is caused by pseudo spread of the vapor-deposition source opening 31, the number thereof at the center portion of the limiting-plate opening 21 in the Y-axis direction in plan view is also highest.

Therefore, in a case where the opening width of the gas injection port 41 is constant regardless of the position thereof in the Y-axis direction, the gas flow rate in the Y-axis direction is constant, and the gas flow rate at the edge in the Y-axis direction, at which the number of vapor deposition particles 301 as the cause of the occurrence of abnormal film forming is relatively small is wastefully high.

Thus, in order to reduce wasteful consumption of the gas and to block the vapor deposition particles 301 as the cause of the occurrence of abnormal film forming with high efficiency, in the gas injection port 41 provided in each of the limiting plates 22, in plan view, the opening width of a portion adjacent to the vapor-deposition source opening 31 in the X-axis direction is preferably set to be wider than the opening width of the gas injection port 41 at an edge in the Y-axis direction (in other words, in plan view, opening width of a portion which is not adjacent to the vapor-deposition source opening 31 in the X-axis direction).

For this, for example, it is desirable that the opening width of the gas injection port 41 is set to be increased as the gas injection port 41 becomes closer to the vapor-deposition source opening 31 and to be reduced as the gas injection port 41 becomes farther from the vapor-deposition source opening 31, in the Y-axis direction.

In the embodiment, regarding the gas injection ports 41, in the limiting plate 22, the opening width thereof at a portion adjacent to the center portion of the limiting-plate opening 21 in the Y-axis direction, which is next above the vapor-deposition source opening 31 (in other words, opening width of the gas injection port 41 at a portion adjacent to the vapor-deposition source opening 31 in the X-axis direction in plan view) is set to be widest. Thus, the gas injection port has a tapered shape in accordance with being close to the edge in the Y-axis direction (that is, in accordance with being far from the vapor-deposition source opening 31 in plan view). The vapor deposition device 100 according to the embodiment is the same as, for example, the vapor deposition device 100 according to Embodiment 1 except for the above configuration.

The gas injection port 41 may be an oval shape or a diamond shape so long as the gas injection port 41 has the above-described shape.

Since the gas injection port 41 has the above-described shape, it is possible to reduce wasteful consumption of the gas and to block the vapor deposition particles 301 as the cause of the occurrence of abnormal film forming with high efficiency. Therefore, it is possible to optimize the gas flow rate in accordance with the position in the Y-axis direction.

FIGS. 6(a) and 6(b) illustrates, an example, a case where one gas injection port 41 is provided in each of the limiting plates 22. However, a plurality of gas injection ports 41 may be provided for one limiting plate 22.

### Embodiment 4

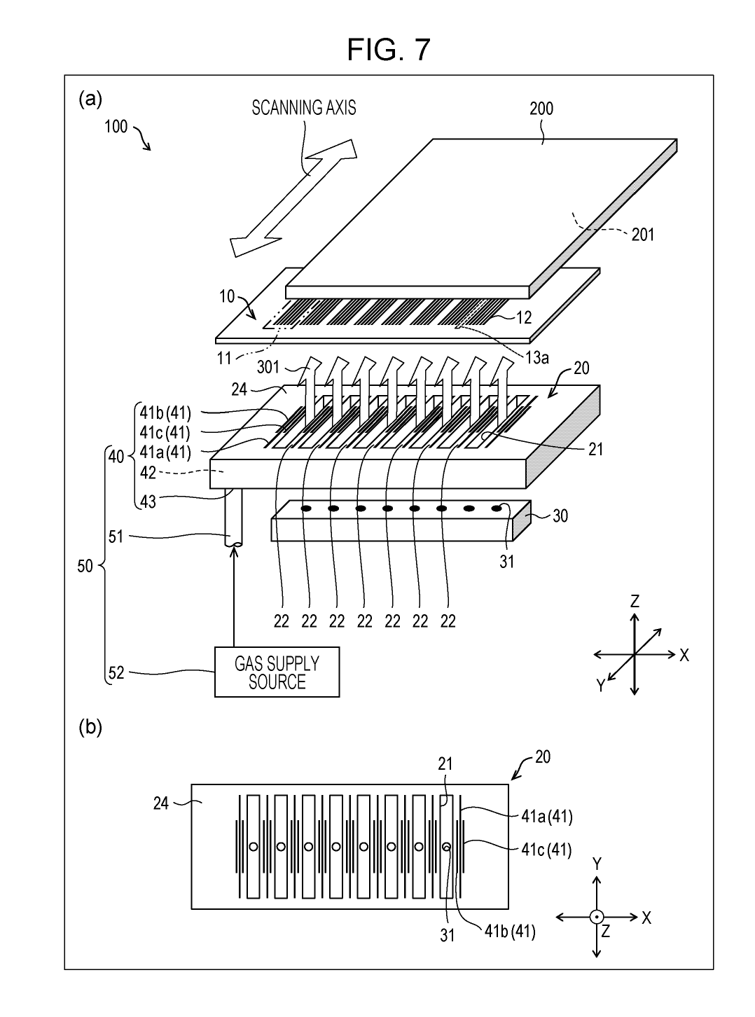

An embodiment will be described with reference to FIGS. 7(a) and 7(b), as follows. In the embodiment, a difference from Embodiments 1 to 3 will be described. Components having the same function as the component used in Embodiments 1 to 3 are denoted by the same reference signs, and descriptions thereof will be not repeated. A difference from the vapor deposition device 100 in Embodiment 3 will be described below as an example. However, modifications similar to Embodiment 1 and Embodiment 2 may be made.

FIG. 7(a) is a perspective view illustrating a basic configuration of a vapor deposition device 100 according to the embodiment. FIG. 7(b) is a plan view illustrating a schematic configuration of the main components of the vapor deposition device 100 illustrated in FIG. 7(a). FIG. 7(b) illustrates a state where the limiting plate unit 20 and the vapor deposition source 30 in the vapor deposition device 100 are viewed from the upper part of the limiting plate unit 20.

As described in Embodiment 3, in order to reduce wasteful consumption of the gas and to block the vapor deposition particles 301 as the cause of the occurrence of abnormal film forming with high efficiency, in the gas injection port 41 provided in each of the limiting plates 22, in plan view, the opening width of a portion adjacent to the vapor-deposition source opening 31 in the X-axis direction (that is, opening length of the gas injection port 41 in the X-axis direction perpendicular to the scanning direction) is preferably set to be wider than the opening width of the gas injection port 41 at an edge in the Y-axis direction (in other words, in plan view, opening width of a portion which is not adjacent to the vapor-deposition source opening 31 in the X-axis direction).

In the embodiment, instead of forming gas injection ports 41 so as to cause the opening width of the gas injection port 41 to vary depending on the position in the Y-axis direction, as in Embodiment 3, as illustrated in FIGS. 7(a) and 7(b), a plurality of gas injection ports 41a to 41c are provided in each of the limiting plates 22, as the gas injection port 41. The gas injection ports 41a to 41c includes the gas injection port 41a having a scanning-direction opening length (that is, opening length of the gas injection port 41 in the Y-axis direction) which is different from those of the gas injection ports 41b and 41c.

In FIGS. 7(a) and 7(b), the gas injection ports 41b and 41c having a scanning-direction opening length which is longer than that of the gas injection port 41a are disposed so as to interpose the gas injection port 41a having the longest scanning-direction opening length. As described above, in the embodiment, at least three gas injection ports 41 (for example, gas injection ports 41a to 41c) are provided between the limiting-plate openings 21 which are adjacent to each other. In addition, the gas injection ports 41 are formed such that the scanning-direction opening length of the gas injection port 41 (for example, gas injection ports 41b and 41c which are adjacent to the limiting-plate opening 21 in plan view) which is relatively close to the limiting-plate opening 21 in plan view is shorter than the scanning-direction opening length of another gas injection port 41 (for example, gas injection port 41).

Therefore, in the embodiment, disposition density of the gas injection port 41 is relatively high in a region which is relatively close to the vapor-deposition source opening 31 in plan view. Disposition density of the gas injection port 41 is relatively low in a region which is relatively far from the vapor-deposition source opening 31. The vapor deposition device 100 according to the embodiment is the same as, for example, the vapor deposition device 100 according to Embodiment 3 except for the above configuration.

In the embodiment, as described above, since a plurality of gas injection ports 41a to 41c having different scanning-direction opening lengths are provided in one limiting plate 22 as the gas injection port 41, the gas injection ports 41a to 41c are provided at a portion of the limiting plate 22, which is adjacent to the center portion of the limiting-plate opening 21 in the Y-axis direction in plan view (portion adjacent to the vapor-deposition source opening 31 in the X-axis direction in plan view), as the gas injection port 41. In addition, only the gas injection port 41a is provided as the gas injection port 41, at a portion of the limiting plate 22, which is adjacent to the limiting-plate opening 21 in the Y-axis direction edge.

Therefore, in the embodiment, the total opening width of the gas injection ports 41 provided in the limiting plates 22, at a portion of the limiting plate 22, which is adjacent to the center portion of the limiting-plate opening 21 in the Y-axis direction, is wider than the total opening width thereof at a portion of the limiting plate 22, which is adjacent to the edge of the limiting-plate opening 21 in the Y-axis direction, by the opening widths of the gas injection ports 41b and 41c.

In this manner, in the embodiment, in plan view, in the vapor deposition device 100, the total opening width of the gas injection ports 41 at a portion which is adjacent to the center portion of the limiting-plate opening 21 in the Y-axis direction is set to be wider than the total opening width of the gas injection ports 41 at a portion which is adjacent to the edge of the limiting-plate openings 21 in the Y-axis direction. More specifically, in the embodiment, the total opening width of the gas injection ports 41 at a portion of the limiting plate 22, which is adjacent to the center portion of the limiting-plate opening 21 in the Y-axis direction (that is, the sum of the opening widths of the gas injection port 41a to 41c provided in each of the limiting plates 22) is set to be wider than the total opening width of the gas injection ports 41 at a portion which is adjacent to the edge of the limiting plate 22 in the Y-axis direction (that is, opening width of the gas injection port 41a which is the gas injection port 41 provided at a portion of the limiting plate 22, which is adjacent to the edge of the limiting-plate openings 21 in the Y-axis direction).

Accordingly, in the embodiment, it is also possible to optimize the gas flow rate in accordance with the position in the Y-axis direction, similar to Embodiment 3.

In FIGS. 7(a) and 7(b), as described above, the gas injection ports 41b and 41c having a scanning-direction opening length which is longer than that of the gas injection port 41a are disposed so as to interpose the gas injection port 41a having the longest scanning-direction opening length. However, the arrangement of the gas injection ports 41 is not limited thereto so long as the gas injection ports 41 are arranged so as to cause the total opening width of the gas injection ports 41 at a portion of the limiting plate 22, which is adjacent to the center portion (that is, portion next above the vapor-deposition source opening 31) of the limiting-plate opening 21 in the Y-axis direction to be wider than the total opening width of the gas injection ports 41 at the edge of the limiting plate 22 in the Y-axis direction.

### Embodiment 5

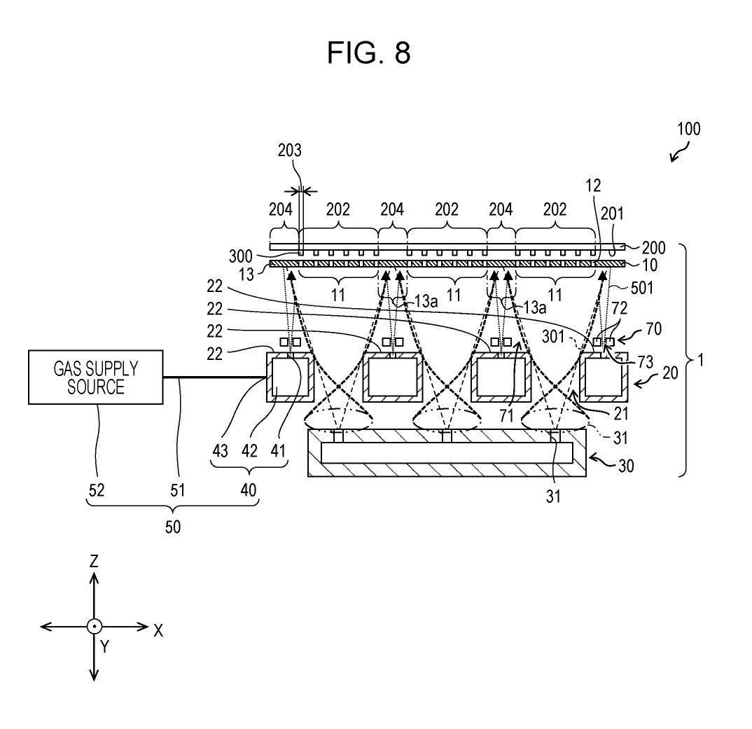

An embodiment will be described with reference to FIG. 8, as follows. In the embodiment, a difference from Embodiments 1 to 4 will be described. Components having the same function as the component used in Embodiments 1 to 4 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiments 2 to 4 may be made.

FIG. 8 is a sectional view illustrating a basic configuration of a vapor deposition device 100 according to the embodiment.

As illustrated in FIG. 8, the vapor deposition device 100 according to the embodiment is the same as, for example, the vapor deposition device 100 according to Embodiment 1 except that a limiting plate unit (second limiting plate unit) 70 for the gas injection port 41 is provided between the limiting plate unit (first limiting plate unit) 20 and the vapor deposition mask 10.

The limiting plate unit 70 includes a plurality of limiting plates (second limiting plate, limiting portion) 72 which face the limiting plate 22 in plan view and are provided to be separated from each other.

A plurality of the limiting plates 72 are provided in one gas injection port 41 in the X-axis direction, so as to interpose the gas injection port 41 in plan view.

In the example illustrated in FIG. 8, a pair of the limiting plates 72 are provided for one limiting plate 22, on the limiting plate (first limiting plate) 22 along the limiting plate 22 in the X-axis direction.

Therefore, each of the limiting plates 72 is provided to be extended in parallel to the Y axis in plan view. A plurality of limiting plates 72 of each pair (that is, pair of limiting plates 72 and 72) are arranged to be parallel to each other at the same pitch in the X-axis direction.

Thus, a limiting-plate opening 71 for a vapor deposition flow is formed between the limiting plates 72 of a pair, which are adjacent to each other in the X-axis direction. The limiting-plate opening 71 is used for causing vapor deposition particles 301 which have passed through the limiting-plate opening 21 between the limiting plates 22 which are adjacent to each other to pass through.

A limiting-plate opening 73 for a gas (gas wall 501) is formed between limiting plates 72 which are provided over the same limiting plate 22 in plan view and form a pair. The limiting-plate opening 73 is used for causing a gas injected from the gas injection port 41 to pass through.

Therefore, two kinds of limiting-plate opening 71 and limiting-plate opening 73 which have different opening widths are alternately provided in the limiting plate unit 70. Each of the limiting-plate openings 71 and 73 is a penetration port that penetrates the limiting plate unit 70 in the Z-axis direction.

The limiting-plate opening 71 and the limiting-plate opening 21 have a one-to-one relationship. Accordingly, the limiting-plate opening 71 has a one-to-one relationship with the mask opening region 11 and the vapor-deposition source opening 31. The limiting-plate opening 73 and the gas injection port 41 have a one-to-one relationship.

Even if the flow rate of a gas injected from the gas injection port 41 is small, the gas may be discharged so as to be slightly diffused at the gas injection port 41, and thus may flow into the film forming target region 202 from the mask opening region 11. As described in Embodiment 1, it is possible to improve directivity by increasing the depth (nozzle length) of the gas injection port 41. However, the method of improving the directivity by using only the depth of the gas injection port 41 has limitation. Thus, if the limiting plate unit 70 having a limiting-plate opening 73 for controlling the gas flow is provided over the gas injection port 41, it is possible to prevent the gas flow from flowing into the mask opening region 11.

That is, the limiting-plate opening 73 has a function of controlling a flow (gas flow) of a gas injected from the gas injection port 41 and improving directivity. The limiting-plate opening 71 has a function of controlling a flow (vapor deposition flow) of vapor deposition particles 301 which have passed through the limiting-plate opening 21 and further improving directivity.

The relative position of the limiting plate 72 to the gas injection port 41, the opening size (scanning-direction opening length and opening width) of the limiting-plate openings 71 and 73, and the like can be optimized in accordance with the width of the limiting plate 72, the height of the limiting plate 72, the distance between the film forming target substrate 200 and the vapor deposition source 30, and the design value of the mask opening region 11 or the like.

It is necessary that the length of the limiting plate 72 in the scanning direction in plan view is set to have a length (that is, length equal to or longer than the gas wall 501 in the Y-axis direction) which is be equal to or longer than the scanning-direction opening length of the gas injection port 41. If the length of the limiting plate 72 in the scanning direction in plan view is shorter than the scanning-direction opening length of the gas injection port 41, it may not be possible to control the gas flow at an edge in the scanning direction.

Therefore, in the embodiment, the appearance of the limiting plate unit 70 is formed to have, for example, a size (for example, the same size) which is substantially equal to that of the limiting plate unit 20 in plan view. However, it is not limited thereto.

If the position of the edge of the limiting plates 72 in the direction perpendicular to the scanning direction in plan view exceeds the position of the edge of the limiting plates 22 in the direction perpendicular to the scanning direction, the limiting plate 72 may interfere with the original vapor deposition flow for forming a normal vapor deposition film 300, and thus it may be not possible to perform normal vapor deposition. Therefore, it is desirable that the limiting plates 72 are arranged so as to cause the position of the edge of the limiting plates 72 in the direction perpendicular to the scanning direction in plan view not to exceed the position of the edge of the limiting plates 22 in the direction perpendicular to the scanning direction.

According to the embodiment, as described above, since the limiting plate unit 70 is provided, it is possible to more reliably prevent the gas flow from flowing into the film forming target region 202.

### Embodiment 6

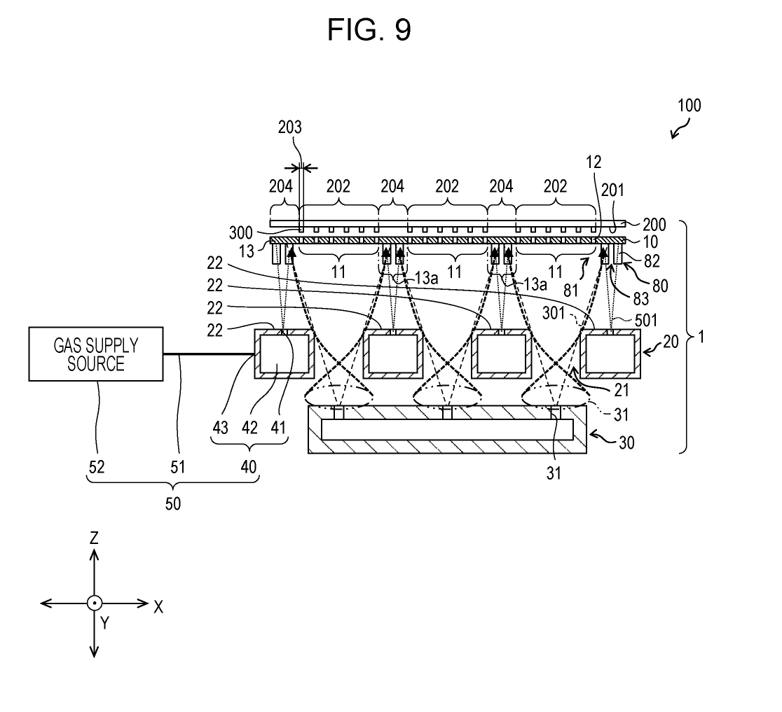

An embodiment will be described with reference to FIG. 9, as follows.

In the embodiment, a difference from Embodiments 1 to 5 will be described. Components having the same function as the component used in Embodiments 1 to 5 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiments 2 to 5 may be made.

FIG. 9 is a sectional view illustrating a basic configuration of a vapor deposition device 100 according to the embodiment.

As illustrated in FIG. 9, the vapor deposition device 100 according to the embodiment is the same as, for example, the vapor deposition device 100 according to Embodiment 1 except that a limiting plate (shielding plate, third limiting plate) 82 that faces the non-opening portions 13 which interpose the mask opening region 11 in the vapor deposition mask 10 and restricts diffusion of a gas, and thus prevents inflow (invasion) of the gas into the mask opening region 11 is provided.

As described above, even if the flow rate of a gas injected from the gas injection port 41 is small, the gas may be discharged so as to be slightly diffused at the gas injection port 41, and thus may flow into the film forming target region 202 from the mask opening region 11.

In addition, the gas flow rate is low and a vapor deposition flow which is used for forming a vapor deposition film 300 which is originally obtained by vapor deposition and has high density of vapor deposition particles 301 is formed between the limiting-plate opening 21 and the mask opening region 11. Thus, even if it is difficult to diffuse a gas sprayed to the vapor deposition mask 10, to the mask opening region 11 side, the gas may be diffused to the mask opening region 11 side in a manner that the gas is brought into contact (that is, collides) with the surface of the vapor deposition mask 10, for example, by the gas flow rate and the like.

Interference between the vapor deposition flow incident to the vapor deposition mask 10 with the gas flow occurs at the edge of the mask opening region 11.

In the embodiment, a limiting plate 82 for restricting diffusion (movement) of a gas is installed so as to interpose the mask opening region 11 in the vapor deposition mask 10. Thus, it is possible to prevent invasion of the gas flow from the mask opening region 11 into the film forming target region 202.

The limiting plate 82 may be directly provided in the vapor deposition mask 10 or may be provided so as to be separate from the vapor deposition mask 10. For example, the vapor deposition mask 10 may be processed, and thus the limiting plate 82 may be provided on a surface (that is, surface which faces the limiting plate unit 20) of the vapor deposition mask 10, which is opposite to the film forming target substrate 200. In addition, the limiting plate unit may be provided in a manner that the mask frame for fixing the edge of the vapor deposition mask 10 is processed, for example, by welding the vapor deposition mask 10. That is, the limiting plate 82 is provided in the mask frame, and thus the mask frame itself may be used as the limiting plate unit. Alternatively, a limiting plate unit may be additionally provided in the mask frame.

If the limiting plate 82 is directly provided in the vapor deposition mask 10, self-weight deflection of the vapor deposition mask 10 is promoted. Therefore, normal vapor deposition may not be performed by the size of the vapor deposition mask 10. If a limiting plate unit which is separate from the mask frame is provided, the number of components is increased. Thus, manufacturing efficiency and alignment efficiency of the vapor deposition device 100 are decreased. Thus, suitably, the limiting plate unit may be provided by processing the mask frame.

FIG. 9 illustrates, an example, a case where a limiting plate unit (third limiting plate unit, shielding unit) 80 is provided between the vapor deposition mask 10 and the limiting plate unit 20. The limiting plate unit 80 is provided so as to be adjacent to the vapor deposition mask 10 and restricts movement of each of a gas and the vapor deposition particles 301.

The limiting plate unit 80 restricts diffusion (movement, moving range) of a gas, and thus prevents inflow (invasion) of the gas into the mask opening region 11. In addition, the limiting plate unit 80 restricts movement (moving range) of the vapor deposition particles 301 to be within the mask opening region 11 in which the vapor deposition particles are originally incident, and thus prevents inflow (invasion) of the vapor deposition particles 301 into the mask opening region (adjacent mask region) 11 which is adjacent to this mask opening region 11.

The thickness of the limiting plate unit 80, that is the thickness of the limiting plate 82 is not limited. However, if the thickness thereof is set to be equal to the thickness of the mask frame, labor for manufacturing the mask frame is not taken.

In the embodiment, as an example, a case where the limiting plate 82 is provided in the mask frame, and thus the limiting plate unit 80 also functions as the mask frame is described. However, as described above, the embodiment is not limited thereto.

For example, a pair of the limiting plates 82 is provided in the X-axis direction so as to interpose the gas wall 501. That is, a plurality of the limiting plates 82 are provided for one non-opening portion 13, in X-axis direction so as to interpose the gas wall 501 in plan view. Thus, a plurality of limiting plates 82 of each pair (that is, pair of limiting plates 82 and 82) which is provided in the X-axis direction in plan view are arranged in the limiting plate unit 80, so as to be parallel to each other at the same pitch in the X-axis direction, and to interpose the mask opening region 11.

It is necessary that the length of the limiting plate 82 in the scanning direction in plan view is set to have a length (that is, length equal to or longer than the gas wall 501 in the Y-axis direction) which is be equal to or longer than the scanning-direction opening length of the gas injection port 41. If the length of the limiting plate 82 in the scanning direction in plan view is shorter than the scanning-direction opening length of the gas injection port 41, it may not be possible to control the gas flow at an edge in the scanning direction.

According to the embodiment, it is prevented that the gas flow spray to a gap (limiting-plate opening for a gas) 83 between the limiting plates 82 which form a pair and are adjacent to each other is blocked flows into the mask opening region 11, by the pair of the limiting plates 82 which interpose the gas flow. A vapor deposition flow which has flown into an opening (limiting-plate opening for a vapor deposition flow) 81 between the limiting plates 82 of the adjacent sets is guided into the mask opening region 11 in which the vapor deposition flow is originally incident, by the gas wall 501 and the limiting plates 82 which interpose the mask opening region 11, and thus inflow into the adjacent mask region is blocked.

That is, the flow of a gas in X-axis direction is regulated on the inner walls of the limiting plates 82 which form a pair, and the flow of vapor deposition particles 301 is regulated on the outer walls of the limiting plates 82 which form a pair. Since the vapor deposition particles 301 pass through the limiting-plate opening 21, directivity is improved. The vapor deposition particles 301 which is incident to the opening 81 in the limiting plate unit 80 are incident to the mask openings 12 in the mask opening region 11.

According to the embodiment, since the limiting plate unit 80 is provided, it is possible to reliably prevent invasion of the gas flow into the film forming target region 202.

As illustrated in FIG. 9, since a plurality of limiting plates 82 which are arranged to be separated from each other are provided in the non-opening portion 13a between the mask opening regions 11, there are advantages in that it is possible to efficiently block a gas flow toward the mask opening region 11 and it is possible to reduce the weight of the entirety of the limiting plate unit 80 because it is possible to reduce the size of each of the limiting plates 82.

In the example illustrated in FIG. 9, as an example, a case where a pair of limiting plates 82 is provided in the X-axis direction so as to face the non-opening portions 13 which interpose each of the mask opening regions 11 in the X-axis direction and interpose the gas wall 501 is described. However, regarding the mask opening regions 11 at both ends of the vapor deposition mask 10 in the X-axis direction, it is not necessary that the gas wall 501 is formed on the outside of the mask opening region 11, and inflow of a gas into the mask opening region 11 which is adjacent to one side of the gas wall 501 may be blocked even if the gas wall 501 is provided.

Therefore, one limiting plate 82 may be formed in the non-opening portion 13 on the outside of the mask opening region 11 at both ends of the vapor deposition mask 10 in the X-axis direction, so as to face the non-opening portion 13.

### Embodiment 7

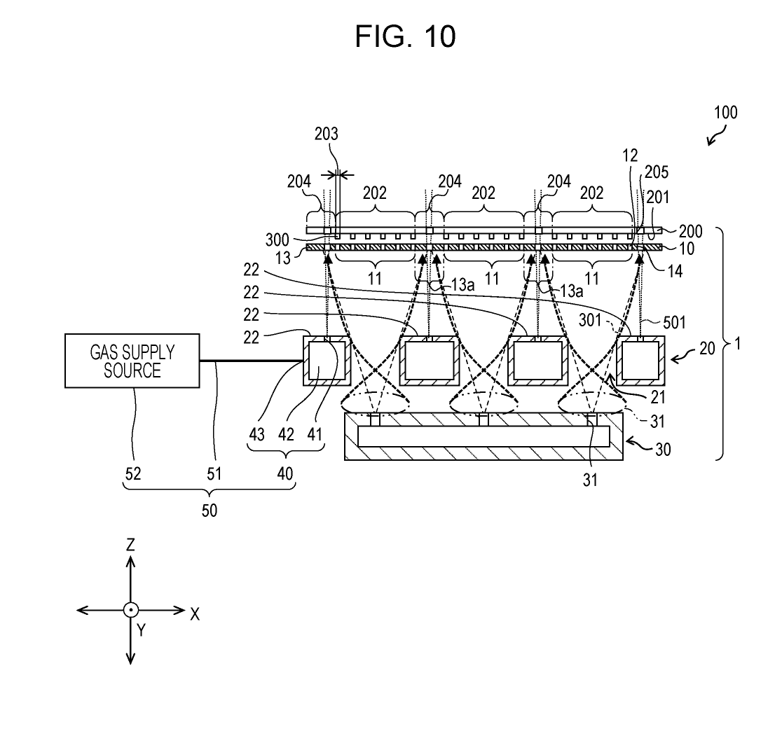

An embodiment will be described with reference to FIG. 10, as follows. In the embodiment, a difference from Embodiments 1 to 6 will be described. Components having the same function as the component used in Embodiments 1 to 6 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiments 2 to 6 may be made.

FIG. 10 is a sectional view illustrating a basic configuration of a vapor deposition device 100 according to the embodiment.

As illustrated in FIG. 10, the vapor deposition device 100 according to the embodiment is the same as, for example, the vapor deposition device 100 according to Embodiment 1 except for points as follows. That is, a mask opening (second mask opening, penetration port) 14 for a gas is provided in the vapor deposition mask 10, so as to face the gas injection port 41. The mask opening 14 is used for causing a gas injected from the gas injection port 41 to pass through. A film forming target substrate 200 in which a penetration port (film forming target substrate opening) 205 which faces the gas injection port 41 and the mask opening 14 is provided in the non-film forming regions 204 which interpose the film forming target region 202 is used as the film forming target substrate 200.

As described above, the gas flow rate is low and a vapor deposition flow which is used for forming a vapor deposition film 300 which is originally obtained by vapor deposition and has high density of vapor deposition particles 301 is formed between the limiting-plate opening 21 and the mask opening region 11. Thus, it is difficult to diffuse a gas sprayed to the vapor deposition mask 10, to the mask opening region 11 side. However, the gas may be diffused to the mask opening region 11 side in a manner that the gas sprayed to the vapor deposition mask 10 is brought into contact (that is, collides) with the surface of the vapor deposition mask 10, for example, by the gas flow rate and the like.

In the embodiment, the amount of a gas mixed in the mask opening region 11 is significantly reduced. Thus, the mask opening 14 for a gas, which is used for causing the gas to pass therethrough is provided, as a loophole of the gas, in the non-opening portions 13 which interpose the mask opening region 11 in the vapor deposition mask 10. In addition, the penetration port 205 for a gas, which is used for causing the gas to pass therethrough is provided, as a loophole of the gas, in the non-film forming regions 204 which interpose the film forming target region 202 in the film forming target substrate 200.

Thus, the gas sprayed from the gas injection port 41 to the surface of the vapor deposition mask 10 escapes to a side of the film forming target substrate 200, which is opposite to the film forming target surface 201, through the mask opening 14 and the penetration port 205. That is, in the embodiment, the gas wall 501 is formed to penetrate the vapor deposition mask 10 and the film forming target substrate 200. Therefore, it is possible to more reliably prevent an occurrence of a situation in which the gas which has collided with the surface of the vapor deposition mask 10 is diffused to the mask opening region 11 side and flows into the mask opening region 11.

According to the embodiment, since the mask opening 14 and the penetration port 205 are formed, as described above, the gas wall 501 can be formed to pass through the vapor deposition mask 10 and the film forming target substrate 200. Therefore, it is possible to more reliably prevent an occurrence of a situation in which vapor deposition particles 301 which have passed through the mask openings 12 are incident to the film forming target region (adjacent film forming target region) 202 which is adjacent to the film forming target region 202 in which the vapor deposition particles 301 are originally incident, over the gas wall 501.

In addition, as described above, since the mask opening 14 and the penetration port 205 are formed, it is possible to increase the gas flow rate in comparison to a case where the mask opening 14 and the penetration port 205 are not formed. Therefore, it is possible to form a gas wall 501 which has more improved blocking properties of vapor deposition particles 301 as the cause of the occurrence of abnormal film forming.

It is desirable that each of the opening length and the opening width of the mask opening 14 and the penetration port 205 in the scanning-direction is equal to the length of the gas wall 501 (which is formed between the vapor deposition mask 10 and the limiting plate unit 20) in the Y-axis direction and the width of the gas wall 501 in the X-axis direction. Therefore, it is preferable that the mask opening 14 and the penetration port 205 are formed so as to cause the scanning-direction opening length and the opening width of the mask opening 14 and the penetration port 205 to be equal to those of the gas injection port 41 in plan view or to be set in consideration of the size of the gas injection port 41 and diffusion of the gas. It is preferable that the mask opening 14 and the penetration port 205 are formed to have a shape which is, for example, similar to that of the gas injection port 41.

In a case where the mask opening 14 is provided in the vapor deposition device 100 according to Embodiment 6, the mask opening 14 is provided in a region of the vapor deposition mask 10, which corresponds to the gap 83 between the limiting plates 82 which are adjacent to each other.

### Embodiment 8

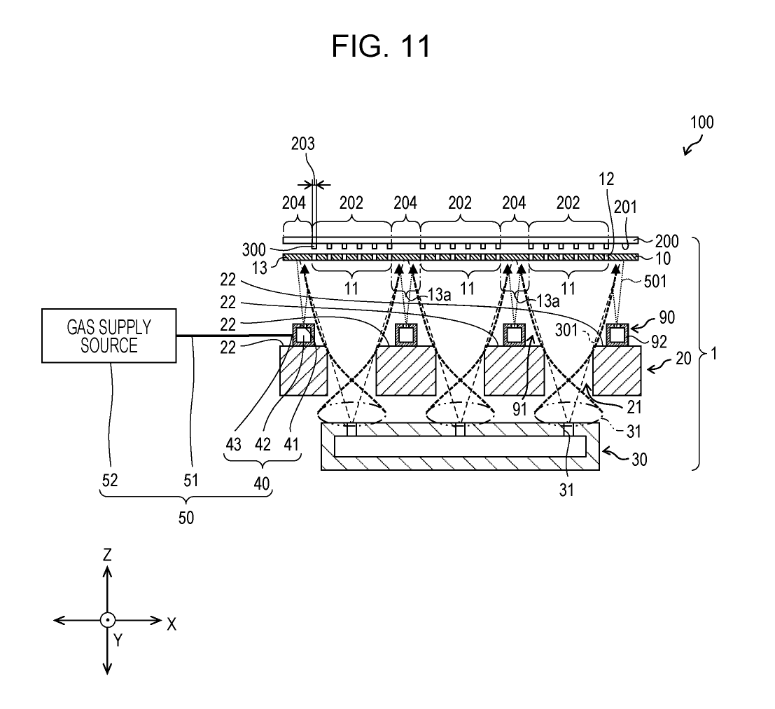

An embodiment will be described with reference to FIG. 11, as follows. In the embodiment, a difference from Embodiments 1 to 7 will be described. Components having the same function as the component used in Embodiments 1 to 7 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiments 2 to 7 may be made.

FIG. 11 is a sectional view illustrating a basic configuration of a vapor deposition device 100 according to the embodiment.

In Embodiments 1 to 7, as an example, a case where the gas injection unit 40 is provided in the limiting plate unit 20 is described. However, the gas wall 501 may be formed between the vapor deposition mask 10 and the limiting plate unit 20 such that it is possible to prevent an occurrence of a situation in which vapor deposition particles 301 which have passed through the limiting-plate opening 21 and act as the cause of the occurrence of abnormal film forming are incident to the adjacent mask opening region.

Accordingly, the gas injection unit 40 may be provided between the vapor deposition mask 10 and the limiting plate unit 20, so as to be separate from the limiting plate unit 20.

The vapor deposition device 100 according to the embodiment includes a limiting plate unit (second limiting plate unit, gas injection unit) 90 instead of providing the gas injection unit 40 in the limiting plate unit 20. The limiting plate unit 90 includes the gas injection unit 40, as a limiting plate-gas supply unit, between the vapor deposition mask 10 and the limiting plate unit 20, so as to be adjacent to the limiting plate unit 20. The vapor deposition device 100 according to the embodiment is the same as, for example, the vapor deposition device 100 according to Embodiment 1 except for the above configuration.

The limiting plate unit 90 is a unit having a hollow block shape, for example. The limiting plate unit 90 has a configuration in which a plurality of limiting-plate openings 91 and gas injection ports 41 are provided at a constant pitch in the X-axis direction.

The limiting plate unit 90 includes a plurality of limiting plate (second limiting plates, gas injection units) 92 which face the limiting plate 22 and are provided to be separated from each other in plan view.

At least one limiting plate 92 is provided for one limiting plate 22. FIG. 11 illustrates, as an example, a case where one limiting plate 92 is provided at the center portion of the limiting plate 22 in the X-axis direction. In a case where a plurality of gas injection ports 41 is provided for one limiting plate 22, a plurality of gas injection ports 41 may be provided in the limiting plate 92. Limiting plates 92 corresponding to the number of the gas injection ports 41 in the X-axis direction may be provided for one limiting plate 22 in the X-axis direction.

The gas injection ports 41 are provided on a surface of the limiting plate 92, which faces the vapor deposition mask 10.

At least one gas introduction port 43 which is connected to the gas supply source 52 through the gas supply tube 51 is provided in the limiting plate unit 90. The limiting plate unit 90 has, for example, a hollow shape, and includes the gas diffusion chamber 42 joined to the gas introduction port 43.

Therefore, the vapor deposition device 100 according to the embodiment has a configuration in which the limiting plate unit 20 and the gas supply mechanism 50 are provided to be independent from each other.

The limiting-plate opening 91 is a penetration port that penetrates the limiting plate unit 90 in the Z-axis direction. The limiting-plate opening 91 and the limiting-plate opening 21 have a one-to-one relationship. Accordingly, the limiting-plate opening 91 has a one-to-one relationship with the mask opening region 11 and the vapor-deposition source opening 31.

The limiting-plate opening 91 has a function of controlling a flow (vapor deposition flow) of vapor deposition particles 301 which have passed through the limiting-plate opening 21 and further improving directivity.

The gas injection port 41 in the limiting plate unit 90 can be similar to the gas injection port 41 in the limiting plate unit 20, and can be designed similar to the gas injection port 41 in the limiting plate unit 20.

As described above, it is preferable that the scanning-direction opening length of the gas injection port 41 is equal to or longer than the scanning-direction opening length of the limiting-plate opening 21. If the scanning-direction opening length of the gas injection port 41 is shorter than the scanning-direction opening length of the limiting-plate opening 21, a site in which the gas wall 501 exists at a position which is adjacent to the limiting-plate opening 21, and it is not possible to prevent an occurrence of a situation in which vapor deposition particles 301 toward the adjacent mask region are blocked in this site.

Accordingly, it is necessary that the length of the limiting plate 92 in the scanning direction in plan view is set to have a length which is equal to or longer than the scanning-direction opening length of the limiting-plate opening 21.

Therefore, in the embodiment, the appearance of the limiting plate unit 90 is formed to have, for example, a size (for example, the same size) which is substantially equal to that of the limiting plate unit 20 in plan view. However, it is not limited thereto.

If the position of the edge of the limiting plates 92 in the direction perpendicular to the scanning direction in plan view exceeds the position of the edge of the limiting plates 22 in the direction perpendicular to the scanning direction, the limiting plate 92 may interfere with the original vapor deposition flow for forming a normal vapor deposition film 300, and thus it may be not possible to perform normal vapor deposition. Therefore, it is desirable that the limiting plates 92 are arranged so as to cause the position of the edge of the limiting plates 92 in the direction perpendicular to the scanning direction in plan view not to exceed the position of the edge of the limiting plates 92 in the direction perpendicular to the scanning direction.

In the embodiment, the vapor deposition flow is controlled by using the limiting-plate opening 21 formed between the limiting plates 22, and thus only a trace amount of an unnecessary component is blocked by the gas wall 501. Thus, it is possible to also obtain the effects similar to those in Embodiment 1.

If a limiting plate unit 20 shielding unit which is separate from the limiting plate unit 20 is provided, the number of components is increased. Thus, manufacturing efficiency and alignment efficiency of the vapor deposition device 100 are decreased.

However, in the embodiment, the gas supply mechanism 50 is formed to be independent from the limiting plate unit 20. Thus, only the gas supply mechanism 50 may be added to the vapor deposition device 100 in which the limiting plate unit 20 is provided, and it is possible to reduce investment in equipment.

### Embodiment 9

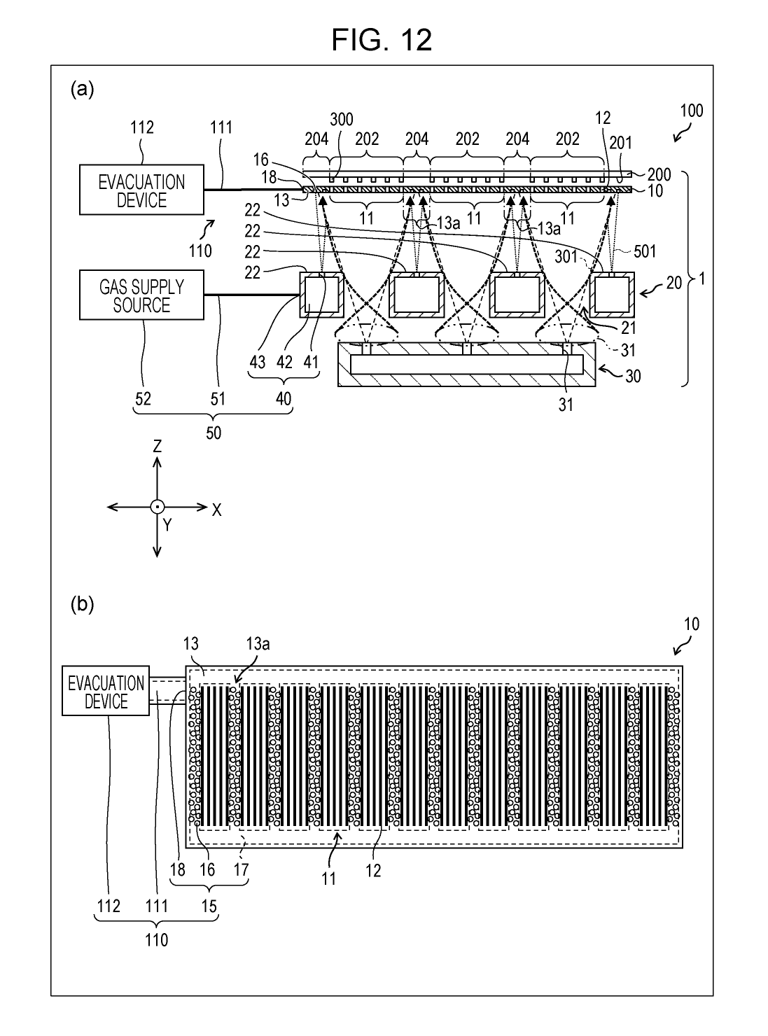

An embodiment will be described with reference to FIGS. 12(a) and 12(b), as follows. In the embodiment, a difference from Embodiments 1 to 8 will be described. Components having the same function as the component used in Embodiments 1 to 8 are denoted by the same reference signs, and descriptions thereof will be not repeated. A difference from the vapor deposition device 100 illustrated in FIG. 1 in Embodiment 1 will be described below as an example. However, modifications similar to the modification example of Embodiment 1 and Embodiments 2 to 6, and 8 may be made.

FIG. 12(a) is a sectional view illustrating a basic configuration of the vapor deposition device 100 according to the embodiment. FIG. 12(b) is a bottom view illustrating a schematic configuration of the vapor deposition mask 10 in which an evacuation mechanism 110 is provided, as illustrated in FIG. 12(a).

As illustrated in FIGS. 12(a) and 12(b), the vapor deposition device 100 according to the embodiment is the same as, for example, the vapor deposition device 100 according to Embodiment 1 except that an evacuation mechanism 110 is provided in the vapor deposition mask 10.

The evacuation mechanism 110 includes a gas suction unit 15 provided in the vapor deposition mask 10, an evacuation device 112, and an evacuation tube 111 which joins the gas suction unit 15 and the evacuation device 112 to each other.

The gas suction unit 15 includes an inlet port 16, an evacuation path 17, and an evacuation port 18.

The inlet port 16 is a gas suction port (opening portion) which is provided on a side of the vapor deposition mask 10, which faces the gas injection port 41 and sucks the gas sprayed to the vapor deposition mask 10. The inlet port 16 is provided in the non-opening portions 13 which face the gas injection port 41 and interpose the mask opening region 11 in the vapor deposition mask 10. That is, in the vapor deposition mask 10 according to the embodiment, the inlet port 16 for sucking a gas for forming the gas wall 501 is provided in a region of the vapor deposition mask 10, in which the gas wall 501 is formed.

The evacuation port 18 connected to the evacuation tube 111 is provided in the vapor deposition mask 10 according to the embodiment. As illustrated in FIG. 12(b), the inlet port 16 and the evacuation port 18 are joined to each other by the evacuation path 17 provided in the vapor deposition mask 10.

The vapor deposition mask 10 may have a hollow structure in which a space portion acting as the evacuation path 17 is provided in a portion which is a penetration port and is other than the mask openings 12, for example, a portion other than the mask opening region 11. The vapor deposition mask 10 may have a structure in which an evacuation tube (ventilation pipe) as the evacuation path (ventilation path) 17 is buried.

The evacuation tube 111 is connected to the evacuation device 112. Thus, a gas sucked from the inlet port 16 is evacuated in a manner that the gas passes in the evacuation path 17 and is sucked from the evacuation port 18 to the evacuation device 112 through the evacuation tube 111.

The evacuation device 112 is disposed on the outside of the film forming chamber 101. For example, an intake device such as a vacuum pump is used as the evacuation device 112. The evacuation device 112 may be provided to separate from a vacuum pump that holds the film forming chamber 101 to be a vacuum state at a time of vapor deposition. The vacuum pump may function as the evacuation device 112. That is, for example, the evacuation tube 111 may be joined to a vacuum pump that holds the film forming chamber 101 to be a vacuum state, by using a branch pipe.

As described in Embodiment 7, the gas may be diffused to the mask opening region 11 side in a manner that the gas sprayed to the vapor deposition mask 10 is brought into contact (that is, collides) with the surface of the vapor deposition mask 10, for example, by the gas flow rate and the like. However, in the embodiment, a gas sprayed to the vapor deposition mask 10 is sucked to the inlet port 16 formed in the vapor deposition mask 10 by the evacuation device 112 connected to the vapor deposition mask 10, and thus the gas is not diffused to the mask opening region 11 side. Therefore, according to the embodiment, it is possible to prevent an occurrence of landing deviation of vapor deposition particles 301 occurring by an unnecessary flow of the gas.

As illustrated in FIG. 12(b), in the embodiment, as an example, a case where a plurality of inlet ports 16 are provided, as the inlet port 16, in the non-opening portions 13 which interpose the mask opening region 11. The inlet port 16 has an opening length which is shorter than that of the mask opening 12 in the Y-axis direction, and has a circular shape in plan view.

However, the shape and the size of the inlet port 16 and the number of inlet ports 16 are not particularly limited so long as the inlet port 16 is formed in a region for forming the gas wall 501 in the vapor deposition mask 10, so as to cause the size of a region for forming one inlet port 16 or forming a plurality of groups of inlet ports 16 to be equal to or greater than that of the gas wall 501.

### Embodiment 10

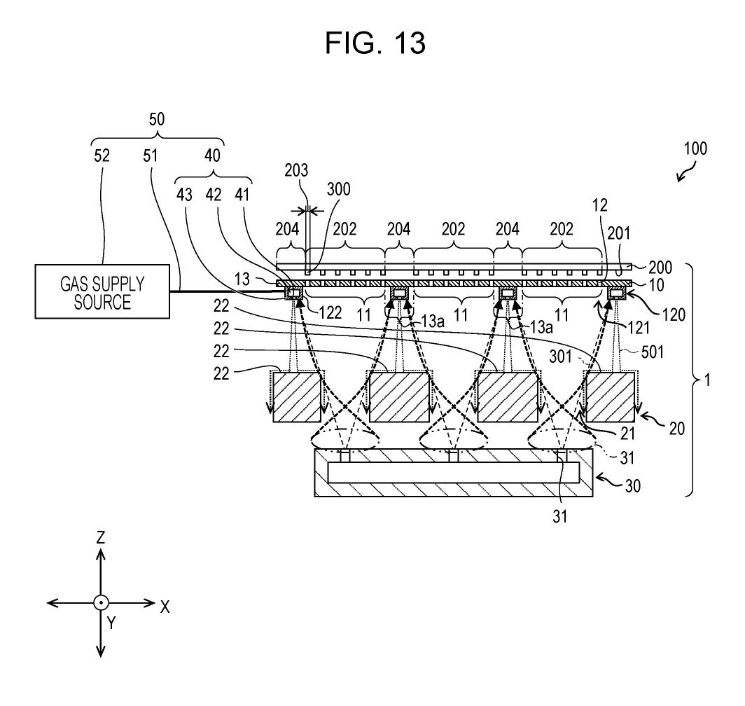

An embodiment will be described with reference to FIG. 13, as follows. In the embodiment, a difference from Embodiments 1 to 9 will be described. Components having the same function as the component used in Embodiments 1 to 9 are denoted by the same reference signs, and descriptions thereof will be not repeated. A difference from the vapor deposition device 100 in Embodiment 8 will be described below as an example. However, modifications similar to Embodiments 1 to 6 may be made.

FIG. 13 is a sectional view illustrating a basic configuration of a vapor deposition device 100 according to the embodiment.

As described above, the gas injection unit 40 may be provided between the vapor deposition mask 10 and the limiting plate unit 20, so as to separate from the limiting plate unit 20.

The vapor deposition device 100 according to the embodiment includes a limiting plate unit (third limiting plate unit, gas injection unit) 120 instead of the limiting plate unit 90. The limiting plate unit 120 is provided between the vapor deposition mask 10 and the limiting plate unit 20, so as to be adjacent to the vapor deposition mask 10 and includes the gas injection unit 40. The vapor deposition device 100 according to the embodiment is the same as, for example, the vapor deposition device 100 according to Embodiment 8 except for the above configuration.

The limiting plate unit 120 is a unit having a hollow block shape, for example. The limiting plate unit 120 has a configuration in which a plurality of limiting-plate openings 121 and gas injection ports 41 are provided at a constant pitch in the X-axis direction.

The limiting-plate openings 121 which are adjacent to each other are separate from each other by a limiting plate (second limiting plate, gas injection unit) 122 that restricts movement of vapor deposition particles 301.

The limiting plate 122 restricts movement (moving range) of the vapor deposition particles 301 to be within the mask opening region 11 in which the vapor deposition particles 301 are originally incident. Thus, the limiting plate 122 prevents inflow (invasion) of the vapor deposition particles 301 to the mask opening region (adjacent mask region) 11 which is adjacent to the mask opening region 11.

The limiting plates 122 are separated from each other in plan view, are arranged at a constant pitch so as to be parallel to each other in the X-axis direction, and are disposed to face the limiting plate 22.

The limiting-plate opening 121 is a penetration port provided between the limiting plates 122 which are adjacent to each other in the X-axis direction.

The gas injection port 41 is provided on a surface of the limiting plate 122, which faces the limiting plate 22.

At least one gas introduction port 43 which is connected to the gas supply source 52 through the gas supply tube 51 is provided in the limiting plate unit 120. The limiting plate unit 120 has, for example, a hollow shape, and includes the gas diffusion chamber 42 joined to the gas introduction port 43.

Therefore, the vapor deposition device 100 according to the embodiment also has a configuration in which the limiting plate unit 20 and the gas supply mechanism 50 are provided to be independent from each other.

The gas injection port 41 in the limiting plate unit 120 can be similar to the gas injection port 41 in the limiting plate unit 20, and can be designed similar to the gas injection port 41 in the limiting plate unit 20.

As described above, it is preferable that the scanning-direction opening length of the gas injection port 41 is equal to or longer than the scanning-direction opening length of the limiting-plate opening 21. If the scanning-direction opening length of the gas injection port 41 is shorter than the scanning-direction opening length of the limiting-plate opening 21, a site in which the gas wall 501 exists at a position which is adjacent to the limiting-plate opening 21, and it is not possible to prevent an occurrence of a situation in which vapor deposition particles 301 toward the adjacent mask region are blocked in this site.

Accordingly, it is necessary that the length of the limiting plate 122 in the scanning direction in plan view is set to have a length which is equal to or longer than the scanning-direction opening length of the limiting-plate opening 21.

Regarding the limiting plate unit 120, the gas injection unit 40 is provided in the mask frame, and thus the mask frame itself may be used as the limiting plate unit 120. Alternatively, the limiting plate unit 120 may be additionally provided in the mask frame.

If a limiting plate unit 120 which is separate from the mask frame is provided, the number of components is increased. Thus, manufacturing efficiency and alignment efficiency of the vapor deposition device 100 are decreased. Thus, suitably, the limiting plate unit 120 may be provided by processing the mask frame.

The thickness of the limiting plate unit 120, that is the thickness of the limiting plate 122 is not limited. However, if the thickness thereof is set to be equal to the thickness of the mask frame, labor for manufacturing the mask frame is not taken.

In the embodiment, as an example, a case where the limiting plate 122 is provided in the mask frame, and thus the limiting plate unit 120 also functions as the mask frame is described. However, as described above, the embodiment is not limited thereto.

The limiting plate unit 120 may have a configuration in which the limiting plates (third limiting plate, gas injection unit) 122 are provided so as to be separated from each other and to face the non-opening portion 13 which interpose the mask opening region 11 in the X-axis direction in plan view and interpose the mask opening region 11.

At least one limiting plate 122 is provided for each of the non-opening portions 13 which interpose the mask opening region 11. That is, at least one limiting plate 122 is provided between the mask opening regions 11 which are adjacent to each other.

FIG. 11 illustrates, as an example, a case where one limiting plate 122 which also functions as the gas injection unit is provided at the center portion between the mask opening regions 11 which are adjacent to each other, in the X-axis direction.

However, the embodiment is not limited thereto. A plurality of gas injection ports 41 may be provided between the mask opening regions 11 which are adjacent to each other. In a case where the plurality of gas injection ports 41 are provided between the mask opening regions 11 which are adjacent to each other, the plurality of gas injection ports 41 may be provided in the limiting plate 122. Limiting plates 122 corresponding to the number of the gas injection ports 41 in the X-axis direction may be provided between the mask opening regions 11 which are adjacent to each other, in the X-axis direction. For example, the gas injection ports 41 may be provided in the limiting plate unit 120 so as to cause two gas injection ports 41 to face one limiting plate 22.

As described above, in the embodiment, since the gas wall 501 is also formed between the vapor deposition mask 10 and the limiting plate unit 20, it is possible to obtain effects similar to those in Embodiment 1.

In addition, in Embodiment 1 to 9, the gas wall 501 is formed in a manner that a gas from the gas injection port 41 is injected from the limiting plate unit 20 side toward the vapor deposition mask 10 side between the limiting plate unit 20 and the vapor deposition mask 10. On the contrary, in the embodiment, the gas wall 501 is formed in a manner that a gas from the gas injection port 41 is injected from the vapor deposition mask 10 side toward the limiting plate unit 20 side between the limiting plate unit 20 and the vapor deposition mask 10.

The vapor deposition particles 301 emitted from the vapor-deposition source opening 31 are substantially isotropically diffused. Thus, the vapor deposition flow is diffused from the limiting plate unit 20 side toward the vapor deposition mask 10 side.

As in Embodiment 1 to 9, in a case where a gas from the gas injection port 41 is injected from the limiting plate unit 20 side toward the vapor deposition mask 10 side, the gas injection port 41 is smaller than the vapor-deposition source opening 31 and the gas flow rate is low. Thus, the gas flow moves more significantly than the vapor deposition flow, but the gas flow is also diffused from the limiting plate unit 20 side toward the vapor deposition mask 10 side. Therefore, gas density on the vapor deposition mask 10 side is lower than that on the limiting plate unit 20 side. In addition, the gas flow is diffused on the vapor deposition mask 10 side, and thus the gas may be intruded into the mask opening region 11. Since the gas is sprayed into the vapor deposition mask 10, the gas which has collided with the surface of the vapor deposition mask 10 may also be spread to the mask opening region 11 side and may flow into the mask opening region 11.

However, in a case where the gas from the gas injection port 41 is injected from the vapor deposition mask 10 side toward the limiting plate unit 20 side, the gas flow is diffused from the vapor deposition mask 10 side toward the limiting plate unit 20 side. Thus, a diffusion direction of the gas flow and a diffusion direction of the vapor deposition flow are reverse to each other. Therefore, control of a gas is easily performed, and the gas wall 501 having high gas density is formed on the vapor deposition mask 10 side. Thus, a force of blocking vapor deposition particles 301 which are directed toward the mask opening regions 11 which are adjacent to each other, between the mask opening regions 11 which are adjacent to each other is increased.

Since the gas is injected from the limiting plate unit 120 toward the limiting plate 22 of the limiting plate unit 20, a situation in which the gas injected from the gas injection port 41 directly flows into the mask opening region 11, in a state of high gas density does not occur.

Further, in the embodiment, the gas from the limiting plate unit 120 is sprayed to the limiting plate 22, and thus the gas which has collided with the surface of the limiting plate 22 flows along the surface of the limiting plate 22. Thus, the gas flow does not hinder the flow of the vapor deposition particles 301. Therefore, the gas does not influence element characteristics.

### Modification Example

In the embodiment, as an example, a case where the limiting plate unit 120 which includes the gas injection unit 40 is provided between the vapor deposition mask 10 and the limiting plate unit 20 is described. However, the embodiment is not limited thereto. The vapor deposition mask 10 may be formed to be hollow as in Embodiment 9 or a ventilation pipe functioning as a ventilation path may be buried in the vapor deposition mask 10, and thus the vapor deposition mask 10 may include the gas supply mechanism 50 instead of the evacuation mechanism 110. That is, the gas injection unit 40 may be provided in the vapor deposition mask 10 itself. In this case, the limiting plate unit 120 is unnecessary, and it is not necessary that the mask frame is the limiting plate unit 120. The gas injection port 41 is directly provided at the non-opening portion 13 in the vapor deposition mask 10.

In this case, if the gas supply source 52 is used in the vapor deposition mask 10 in which the evacuation mechanism 110 is provided, instead of the evacuation device 112, as illustrated in FIG. 12, the evacuation mechanism 110 functions as the gas supply mechanism 50, the gas suction unit 15 functions as the gas injection unit 40, the inlet port 16 functions as the gas injection port 41, the evacuation path 17 functions as the gas diffusion chamber 42, the evacuation port 18 functions as the gas introduction port 43, and the evacuation tube 111 functions as the gas supply tube 51.

Accordingly, the vapor deposition device 100 may have a configuration in which the vapor deposition mask 10 which has the above-described configuration and in which the gas supply mechanism 50 is provided is provided instead of the vapor deposition mask 10 and the limiting plate unit 120 illustrated in FIG. 13.

In the embodiment, as described above, modifications similar to Embodiment 1 to 6 may be made. For example, in the vapor deposition device 100 according to the embodiment, a plurality of gas injection ports 41 are provided for each of the non-opening portions 13 which interpose the mask opening region 11, in the X-axis direction, such that a plurality of gas walls 501 are formed for one limiting plate 22 in the X-axis direction (in other words, such that a plurality of gas walls 501 are formed between the limiting-plate openings 21 which are adjacent to each other in plan view, that is, between the mask opening regions 11 which are adjacent to each other in plan view, in the X-axis direction).

In the embodiment, the gas injection port 41 may have a shape illustrated in any of FIGS. 2, 6(a), 6(b), 7(a), and 7(b) or may have a shape obtained by combining these shapes.

In a case where the gas injection port 41 is provided in the limiting plate unit 120, the limiting plate unit 70 is provided, as the fourth limiting plate unit, between the limiting plate unit 120 and the limiting plate unit 20. The limiting plates 72 are provided so as to interpose the gas injection port 41, and thus the gas flow may be controlled. In this case, it is desirable that the limiting plate unit 70 is provided to be adjacent to the limiting plate unit 120.

In a case where the gas injection port 41 is provided in the vapor deposition mask 10, instead of the limiting plate unit 120, the limiting plate unit 70 as the third limiting plate unit is provided between the vapor deposition mask 10 and the limiting plate unit 20. The limiting plates 72 are provided so as to interpose the gas injection port 41, and thus the gas flow may be controlled. In this case, it is desirable that the limiting plate unit 70 is provided to be adjacent to the vapor deposition mask 10 and also functions as the mask frame.

The limiting plate 82 may be provided in the limiting plate unit 120 or the vapor deposition mask 10, so as to be integrated with the limiting plate unit 120 or the vapor deposition mask 10 and to interpose the gas wall 501 in plan view. The limiting plate unit 80 including the limiting plate 82 may be provided, as the fourth limiting plate unit, so as to be adjacent to the limiting plate unit 120. Alternatively, the limiting plate unit 80 including the limiting plate 82 may be provided, as the third limiting plate unit, so as to be adjacent to the vapor deposition mask 10. In a case where the limiting plate unit 80 is provided to be adjacent to the vapor deposition mask 10, it is desirable that the limiting plate unit 80 also functions as the mask frame.

As described above, in a case where the limiting plate 82 is provided in the limiting plate unit 120 or the vapor deposition mask 10, or the limiting plate unit 80 including the limiting plate 82 is provided to be adjacent to the limiting plate unit 120 or the vapor deposition mask 10, the limiting plate 82 can block inflow of a gas into the mask opening region 11. In addition, similar to the limiting plate 72, the limiting plate 82 can control the flow (gas flow) of a gas injected from the gas injection port 41 and thus it is possible to improve directivity.

### Embodiment 11

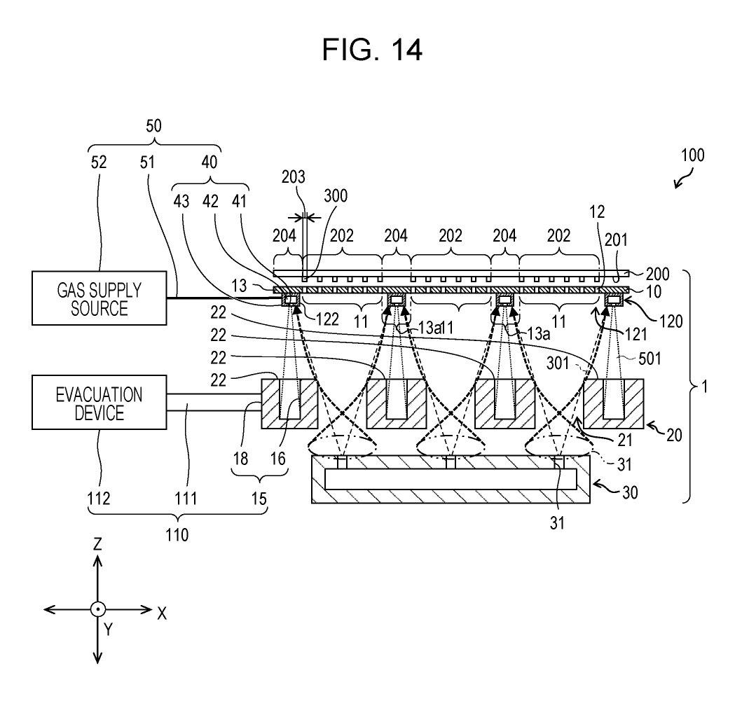

An embodiment will be described with reference to FIG. 14, as follows. In the embodiment, a difference from Embodiments 1 to 10 will be described. Components having the same function as the component used in Embodiments 1 to 10 are denoted by the same reference signs, and descriptions thereof will not be repeated. A difference from the vapor deposition device 100 illustrated in FIG. 13 in Embodiment 10 will be described below as an example. However, in the embodiment, modifications similar to Embodiments 1 to 6 and the modification example of Embodiment 10 may also be made.

FIG. 14 is a sectional view illustrating a basic configuration of a vapor deposition device 100 according to the embodiment.

As illustrated in FIG. 14, the vapor deposition device 100 according to the embodiment is the same as the vapor deposition device 100 according to Embodiment 10 except that the evacuation mechanism 110 is provided in the limiting plate unit 20.

In the embodiment, similar to Embodiment 10, a gas from the gas injection port 41 is injected from the vapor deposition mask 10 side toward the limiting plate unit 20 side. Therefore, in the embodiment, the evacuation mechanism 110 is provided in the limiting plate unit 20 instead of providing the evacuation mechanism 110 in the vapor deposition mask 10 as in Embodiment 9.

The evacuation mechanism 110 according to the embodiment is the same as the evacuation mechanism 110 according to Embodiment 8 except that the evacuation mechanism 110 is provided in the limiting plate unit 20.

That is, the evacuation mechanism 110 includes the gas suction unit 15 provided in the limiting plate unit 20, the evacuation device 112, and the evacuation tube 111 which joins the gas suction unit 15 and the evacuation device 112 to each other. The gas suction unit 15 includes the inlet port 16, the evacuation path (not illustrated), and the evacuation port 18.

The inlet port 16 is provided in a region of forming the gas wall 501 on a surface of the limiting plate 22, which faces the gas injection port 41. Thus, the inlet port 16 sucks a gas which has been sprayed to the limiting plate 22 and is used for forming the gas wall 501.

The evacuation port 18 connected to the evacuation tube 111 is provided in the limiting plate unit 20. The inlet port 16 and the evacuation port 18 are joined to each other by the evacuation path (not illustrated) provided in the limiting plate unit 20.

Similar to the vapor deposition mask 10 in Embodiment 9, the limiting plate unit 20 according to the embodiment may have a hollow structure in which a space portion acting as the evacuation path is provided in a portion which is a penetration port and is other than the limiting-plate openings 21. The limiting plate unit 20 may have a structure in which an evacuation tube as the evacuation path is buried.

In the embodiment, the gas sprayed to the limiting plate 22 is sucked to the inlet port 16 formed in the limiting plate 22 by the evacuation device 112 connected to the limiting plate unit 20, and thus the gas is evacuated. Therefore, the gas does not hinder the flow of vapor deposition particles 301. Therefore, the gas does not influence element characteristics.

### CONCLUSION

According to Aspect 1 of the present invention, the vapor deposition device 100 forms a vapor deposition film 300 having a plurality of predetermined patterns, in a film forming target region 202 of a film forming target substrate 200. The plurality of predetermined patterns are arranged in a first direction (X-axis direction, a direction perpendicular to a scanning direction), and the film forming target substrate 200 includes a plurality of film forming target regions 202 in the first direction. The vapor deposition device 100 includes a vapor deposition source 30, a vapor deposition mask 10, a first limiting plate unit, and a gas supply mechanism 50. The vapor deposition source 30 includes a plurality of vapor-deposition source openings 31 for emitting vapor deposition particles 301. In the vapor deposition mask 10, a mask opening region 11 having a plurality of mask openings 12 which are arranged in the first direction so as to respectively correspond to the patterns of the vapor deposition film 300 is provided. The mask opening region 11 faces each of the plurality of film forming target regions 202. The first limiting plate unit (limiting plate unit 20) is disposed between the vapor deposition source 30 and the vapor deposition mask 10. The first limiting plate unit includes a plurality of first limiting plates (limiting plate 22) which are disposed to be separated from each other in the first direction. A first limiting-plate opening (limiting-plate opening 21) for causing the vapor deposition particles 301 to pass therethrough is provided between the first limiting plates which are adjacent to each other, so as to correspond to the film forming target region 202. The gas supply mechanism 50 causes a gas wall 501 to be formed at a portion between the vapor deposition mask 10 and the first limiting plate unit. The gas wall 501 is formed in the non-opening region (non-opening portion 13, non-opening portion 13a) between the first limiting-plate openings of the first limiting plate unit, which are adjacent to each other in the first direction, and between the mask opening regions 11 of the vapor deposition masks 10 which are adjacent to each other, in plan view.

According to the above configuration, the flow (vapor deposition flow) of the vapor deposition particles 301 is controlled by the limiting-plate opening 21 formed between the limiting plates 22. Thus, an unnecessary vapor deposition particle 301 which is included in the vapor deposition flow passing through the limiting-plate opening 21 and is the cause of the occurrence of abnormal film forming occurring by pseudo spread of the vapor-deposition source opening 31 at a time of a high rate is blocked by the gas wall 501. Accordingly, according to the above configuration, it is possible to block the unnecessary component with high efficiency.

According to the above configuration, only a trace amount of an unnecessary component which is included in the vapor deposition flow passing through the limiting-plate opening 21 may be blocked by the gas wall 501. Thus, the amount of the gas may be small and it is not necessary that the gas wall 501 is formed between the vapor-deposition source opening 31 and the limiting-plate opening 21. Therefore, a situation in which pressure in the vicinity of the vapor-deposition source opening 31 is increased as in a case where a large amount of gas is emitted from the vicinity of the vapor-deposition source opening does not occur. In addition, a situation in which the vacuum degree is significantly decreased does not occur.

Therefore, with the above configuration, it is possible to provide a vapor deposition device in which vapor deposition at a high rate is possible and it is possible to prevent the occurrence of abnormal film forming even in a case where vapor deposition is performed at the high rate.

In the vapor deposition device, since the unnecessary component is blocked by the gas wall 501, the flow rate of the gas may be controlled in accordance with the vapor deposition rate. Therefore, versatility is high in comparison to a case where the unnecessary component is blocked by, for example, only the limiting plate 22.

In a case where the gas is emitted from the vicinity of the vapor-deposition source opening as in PTLs 2 and 3, a large amount of the gas may flow (be intruded) into the film forming target region in comparison to the above aspect. Therefore, in a case where the method disclosed in PTLs 2 and 3 is applied to a case where a plurality of film forming target regions are provided in one film forming target substrate, as described above, and thus the unnecessary component is blocked by only the gas, the gas may largely influence an element such as an organic EL element provided in the film forming target substrate 200.

However, according to the above configuration, since the large amount of the gas does not flow into the mask opening region 11, the gas for forming the gas wall 501 does not have a large influence on characteristics such as element characteristics in the film forming target substrate 200.

Accordingly, according to the above configuration, it is possible to prevent the occurrence of abnormal film forming without largely influencing characteristics of the film forming target substrate 200.

According to Aspect 2 of the present invention, in Aspect 1, in the vapor deposition device 100, a gas injection port 41 may be provided in each of the first limiting plates. The gas injection port 41 may cause the gas for forming the gas wall 501 to be injected toward the non-opening region in the vapor deposition mask 10.

According to the above configuration, the gas is injected from the gas injection port 41 toward the non-opening region of the vapor deposition mask 10. Thus, it is possible to easily form the gas wall 501 between the non-opening region and the first limiting plate.

According to Aspect 3 of the present invention, in Aspect 2, the vapor deposition device 100 may include second limiting plate unit (limiting plate unit 70) between the first limiting plate unit and the vapor deposition mask 10. The second limiting plate unit includes a plurality of second limiting plates (limiting plate 72) which are provided to respectively face the first limiting plates and to be separated from each other in plan view. A plurality of second limiting plates may be provided for one first limiting plate, in the first direction, so as to interpose the gas injection port 41 in plan view.

According to the above configuration, as described above, since the second limiting plate unit is provided, it is possible to more reliably prevent inflow of a gas for forming the gas wall 501 into the film forming target region 202.

According to Aspect 4 of the present invention, in Aspect 1, in the vapor deposition device 100, the gas supply mechanism 50 may include a gas injection unit (limiting plate unit 90 or limiting plate unit 120). The gas injection unit includes a plurality of gas injection ports 41 for causing the gas for forming the gas wall 501 to be injected. The gas injection unit may be provided between the vapor deposition mask 10 and the first limiting plate unit.

According to the above configuration, the gas injection unit is provided to be separate from the first limiting plate unit. Thus, it is possible to form the gas supply mechanism 50 to be independent from the first limiting plate unit. Accordingly, according to the above configuration, only the gas supply mechanism 50 may be added to the vapor deposition device 100 in which the first limiting plate unit is provided, and it is possible to reduce investment in equipment.

According to Aspect 5 of the present invention, in Aspect 4, in the vapor deposition device 100, the gas injection unit may be a second limiting plate unit (limiting plate unit 90) between the first limiting plate unit and the vapor deposition mask 10 so as to be adjacent to the first limiting plate unit. The second limiting plate unit may include a plurality of second limiting plates (limiting plates 92) which are provided to respectively face the first limiting plates and to be separated from each other in plan view. The gas injection ports 41 may be respectively provided in the second limiting plates. The gas injection port 41 may cause the gas for forming the gas wall 501 to be injected toward the non-opening region in the vapor deposition mask 10.

According to the above configuration, the gas is injected from the gas injection port 41 toward the non-opening region of the vapor deposition mask 10. Thus, it is possible to easily form the gas wall 501 between the non-opening region and the first limiting plate.

According to Aspect 6 of the present invention, in any of Aspects 2 to 5, the vapor deposition device 100 may include a third limiting plate unit (limiting plate unit 80) between the first limiting plate unit and the vapor deposition mask 10. The third limiting plate unit may include a plurality of third limiting plates (limiting plate 82) which are provided to be adjacent to the vapor deposition mask 10, and are provided to face the non-opening region between the mask opening regions 11 in the vapor deposition mask 10 and to be separated from each other. A plurality of third limiting plates may be provided for one non-opening region in the first direction, so as to interpose the gas wall 501 in plan view.

According to the above configuration, since the third limiting plate unit is provided, it is possible to more reliably prevent inflow of a gas for forming the gas wall 501 into the film forming target region 202.

According to Aspect 7 of the present invention, in any of Aspects 1 to 6, the vapor deposition device 100 may further include an evacuation device 112. An inlet port 16 which is connected to the evacuation device 112 and sucks the gas for forming the gas wall 501 may be provided in the vapor deposition mask 10.

According to the above configuration, the gas sprayed to the vapor deposition mask 10 is sucked to the inlet port 16 formed in the vapor deposition mask 10 by the evacuation device 112 connected to the vapor deposition mask 10. Thus, diffusion to the mask opening region 11 side does not occur. Therefore, it is possible to prevent an occurrence of landing deviation of vapor deposition particles 301 occurring by an unnecessary flow of the gas.

According to Aspect 8 of the present invention, in any of Aspects 1 to 6, in the vapor deposition device 100, an opening portion (mask opening 14, penetration port 205) for causing the gas for forming the gas wall 501 to pass therethrough may be provided in the vapor deposition mask 10 and the film forming target substrate 200. The gas wall 501 may be formed to penetrate the vapor deposition mask 10 and the film forming target substrate 200.

According to the above configuration, the gas sprayed from the gas injection port 41 to the surface of the vapor deposition mask 10 escapes to a side of the film forming target substrate 200, which is opposite to the film forming target surface 201, through the opening portions which are provided in the vapor deposition mask 10 and the film forming target substrate 200. Therefore, according to the above configuration, it is possible to more reliably prevent an occurrence of a situation in which the gas which has collided with the surface of the vapor deposition mask 10 is diffused to the mask opening region 11 side and flows into the mask opening region 11.

According to the above configuration, it is possible to form the gas wall 501 so as to pass through the vapor deposition mask 10 and the film forming target substrate 200. Therefore, it is possible to more reliably prevent an occurrence of a situation in which vapor deposition particles 301 which have passed through the mask openings 12 are incident to the film forming target region (adjacent film forming target region) 202 which is adjacent to the film forming target region 202 in which the vapor deposition particles 301 are originally incident, over the gas wall 501.

In addition, according to the above configuration, it is possible to increase the gas flow rate in comparison to a case where the opening portion is not formed in the vapor deposition mask 10 and the film forming target substrate 200. Therefore, according to the above configuration, it is possible to form the gas wall 501 which has more improved blocking properties of vapor deposition particles 301 as the cause of the occurrence of abnormal film forming.

According to Aspect 9 of the present invention, in Aspect 4, in the vapor deposition device 100, the gas injection unit may be a third limiting plate unit (limiting plate unit 120). The third limiting plate unit may be provided between the first limiting plate unit and the vapor deposition mask 10, so as to be adjacent to the vapor deposition mask 10. The third limiting plate unit may include a plurality of third limiting plates (limiting plates 122) which are provided to face the non-opening region in the vapor deposition mask 10 and to be separated from each other in plan view. The gas injection ports 41 may be respectively provided in the third limiting plates. The gas injection port 41 may cause the gas for forming the gas wall 501 to be injected toward the first limiting plate (limiting plate 22).

According to the above configuration, the gas is injected from the gas injection port 41 toward the non-opening region of the vapor deposition mask 10. Thus, it is possible to easily form the gas wall 501 between the non-opening region and the first limiting plate.

The gas is injected from the gas injection port 41 toward the non-opening region of the vapor deposition mask 10 in the above-described manner, and thus a diffusion direction of the gas flow and a diffusion direction of the vapor deposition flow are reverse to each other. Therefore, according to the above configuration, the gas is easily controlled and the gas wall having high gas density is formed on the vapor deposition mask 10 side. Thus, a force of blocking vapor deposition particles 301 which are directed toward the mask opening regions 11 which are adjacent to each other, between the mask opening regions 11 which are adjacent to each other is increased.

Since the gas is injected from the third limiting plate unit toward the first limiting plate, a situation in which the gas injected from the gas injection port 41 directly flows into the mask opening region 11, in a state of high gas density, does not occur.

Further, according to the above configuration, since the gas is sprayed from the third limiting plate unit to the first limiting plate, the gas which has collided with the surface of the first limiting plate flows along the surface of the first limiting plate, and thus the gas does not hinder the flow of the vapor deposition particles 301. Therefore, the gas does not influence element characteristics.

According to Aspect 10 of the present invention, in Aspect 6 or 9, in the vapor deposition device 100, the third limiting plate unit (limiting plate unit 80 or limiting plate unit 120) may also function as a mask frame for fixing the edge of the vapor deposition mask 10.

According to the above configuration, it is possible to reduce the number of components and to improve manufacturing efficiency and alignment efficiency of the vapor deposition device 100.

According to Aspect 11 of the present invention, in Aspect 1, in the vapor deposition device 100, a gas injection port 41 for causing the gas for forming the gas wall 501 to be injected toward the first limiting plate may be provided in the non-opening region between the mask opening regions 11 in the vapor deposition mask 10.

According to the above configuration, the gas is injected from the gas injection port 41 toward the non-opening region of the vapor deposition mask 10. Thus, it is possible to easily form the gas wall 501 between the non-opening region and the first limiting plate.

The gas is injected from the gas injection port 41 toward the non-opening region of the vapor deposition mask 10 in the above-described manner, and thus a diffusion direction of the gas flow and a diffusion direction of the vapor deposition flow are reverse to each other. Therefore, according to the above configuration, the gas is easily controlled and the gas wall having high gas density is formed on the vapor deposition mask 10 side. Thus, a force of blocking vapor deposition particles 301 which are directed toward the mask opening regions 11 which are adjacent to each other, between the mask opening regions 11 which are adjacent to each other is increased.

Further, according to the above configuration, since the gas is sprayed from the third limiting plate unit to the first limiting plate, the gas which has collided with the surface of the first limiting plate flows along the surface of the first limiting plate, and thus the gas does not hinder the flow of the vapor deposition particles 301. Therefore, the gas does not influence element characteristics.

According to Aspect 12 of the present invention, in Aspect 9 or 11, the vapor deposition device 100 may further include an evacuation device 112. An inlet port 16 which is connected to the evacuation device 112 and sucks the gas for forming the gas wall 501 may be provided in the first limiting plate.

According to the above configuration, the gas sprayed to the first limiting plate is sucked to the inlet port 16 formed in the first limiting plate by the evacuation device 112 connected to the limiting plate unit 20. Thus, the gas is evacuated. Therefore, the gas does not hinder the flow of vapor deposition particles 301. Therefore, the gas does not influence the element characteristics.

According to Aspect 13 of the present invention, in any of Aspects 2 to 6 and 9 to 12, in the vapor deposition device 100, the gas injection port 41 may be provided such that a plurality of gas walls 501 are formed for one first limiting plate in the first direction.

According to the above configuration, it is possible to increase a probability of blocking unnecessary vapor deposition particles 301 as the cause of the occurrence of abnormal film forming.

According to Aspect 14 of the present invention, in any of Aspects 2 to 6 and 9 to 13, in the vapor deposition device 100, the gas injection port 41 may be provided to be extended along the first limiting-plate opening in a second direction (Y-axis direction, scanning direction) perpendicular to the first direction in plan view. The gas injection port 41 may have a shape in which the opening width (in the first direction) at a portion adjacent to the vapor-deposition source opening 31 in the first direction is widest and is tapered toward the edge in the second direction in plan view.

According to the above configuration, it is possible to reduce wasteful consumption of the gas and to block unnecessary vapor deposition particles 301 as the cause of the occurrence of abnormal film forming with high efficiency.

According to Aspect 15 of the present invention, in any of Aspects 2 to 6 and 9 to 14, in the vapor deposition device 100, in plan view, disposition density of the gas injection ports 41 may be relatively high in a region which is relatively close to the vapor-deposition source opening 31. The disposition density of the gas injection ports 41 may be relatively low in a region which is relatively far from the vapor-deposition source opening 31. The total opening width of the gas injection ports 41 in the first direction in the region which is relatively close to the vapor-deposition source opening 31 may be wider than that in the region which is relatively far from the vapor-deposition source opening 31.

According to the above configuration, it is possible to reduce wasteful consumption of the gas and to block unnecessary vapor deposition particles 301 as the cause of the occurrence of abnormal film forming with high efficiency.

According to Aspect 16 of the present invention, in any of Aspects 2 to 6 and 9 to 15, in the vapor deposition device 100, the gas injection port 41 may be provided between the limiting-plate openings 21 which are adjacent to each other in plan view, so as to cause at least three gas injection ports (for example, gas injection ports 41a to 41c) 41 to be positioned in the first direction (in other words, the gas injection port 41 may be provided between the mask opening regions 11 which are adjacent to each other in plan view, so as to cause at least three gas injection ports (for example, gas injection ports 41a to 41c) 41 to be positioned in the first direction). The opening length (scanning-direction opening length) of the gas injection port (for example, gas injection ports 41b and 41c) 41 which is adjacent to the limiting-plate opening 21 in plan view, in the second direction perpendicular to the first direction may be shorter than the opening length (scanning-direction opening length) of the other gas injection port (for example, gas injection port 41a) 41, in the second direction.

According to the above configuration, it is possible to reduce wasteful consumption of the gas and to block unnecessary vapor deposition particles 301 as the cause of the occurrence of abnormal film forming with high efficiency.

According to Aspect 17 of the present invention, a vapor deposition method is used for forming a vapor deposition film 300 having a plurality of predetermined patterns, in a film forming target region 202 of a film forming target substrate 200. The plurality of predetermined patterns are arranged in a first direction (X-axis direction, direction perpendicular to a scanning direction), and the film forming target substrate 200 has a plurality of film forming target regions 202 in the first direction. The vapor deposition method includes disposing a first limiting plate unit (limiting plate unit 20) between a vapor deposition source 30 and a vapor deposition mask 10, the vapor deposition source 30 having a plurality of vapor-deposition source openings 31 for emitting vapor deposition particles 301, the vapor deposition mask 10 having a mask opening region 11 provided to have a plurality of mask openings 12 arranged in the first direction, the mask opening region provided to face each of the plurality of film forming target regions 202, the mask openings respectively corresponding to the patterns of the vapor deposition film 300, the first limiting plate unit having a plurality of first limiting plates (limiting plate 22) provided to be separated from each other in the first direction, the first limiting plate unit having a first limiting-plate opening (limiting-plate opening 21) between the first limiting plates adjacent to each other, the first limiting-plate opening configured to cause the vapor deposition particles 301 to pass therethrough and to correspond to each of the film forming target regions 202; and forming the vapor deposition film 300 in a manner that the vapor deposition particles 301 are emitted from the vapor deposition source 30 while a gas wall is formed in a non-opening region (non-opening portion 13, non-opening portion 13a) by a gas supply mechanism 50, the non-opening region being a portion between the vapor deposition mask 10 and the first limiting plate unit and being positioned between first limiting-plate openings of the first limiting plate unit, the first limiting-plate openings being adjacent to each other, the non-opening region being positioned between mask opening regions 11 of the vapor deposition mask 10, the mask opening regions 11 being adjacent to each other, in plan view.

According to the above method, it is possible to obtain effects which are similar to those in Aspect 1.

The present invention is not limited to the above-described embodiment. Various changes may be made in a range described in claims, and an embodiment obtained by appropriately combining technical means disclosed in the different embodiments is also included in the technical range of the present invention. Further, new technical features can be formed by combining the technical means disclosed in the embodiments.

### INDUSTRIAL APPLICABILITY

The vapor deposition device and the vapor deposition method according to the present invention can be suitably used in manufacturing of various devices which use vapor deposition, in addition to manufacturing of an EL display device such as an organic EL display device or an inorganic EL display device.

### REFERENCE SIGNS LIST

1 VAPOR DEPOSITION UNIT
10 VAPOR DEPOSITION MASK
11 MASK OPENING REGION
12 MASK OPENING (MASK OPENING FOR VAPOR DEPOSITION FLOW)
13 NON-OPENING PORTION (NON-OPENING REGION)
13a NON-OPENING PORTION (NON-OPENING REGION)
14 MASK OPENING (MASK OPENING FOR GAS, OPENING PORTION)
15 GAS SUCTION UNIT
16 INLET PORT
17 EVACUATION PATH
18 EVACUATION PORT
20 LIMITING PLATE UNIT (FIRST LIMITING PLATE UNIT)
21 LIMITING-PLATE OPENING (FIRST LIMITING-PLATE OPENING)
22 LIMITING PLATE (FIRST LIMITING PLATE)
24 HOLDING BODY PORTION
30 VAPOR DEPOSITION SOURCE
31 VAPOR-DEPOSITION SOURCE OPENING
40 GAS INJECTION UNIT
41, 41a, 41b, 41c GAS INJECTION PORT
42 GAS DIFFUSION CHAMBER
43 GAS INTRODUCTION PORT
50 GAS SUPPLY MECHANISM
51 GAS SUPPLY TUBE
52 GAS SUPPLY SOURCE
60 HOLDER
62 ADHESION PREVENTION PLATE
70 LIMITING PLATE UNIT (SECOND LIMITING PLATE UNIT)
71 LIMITING-PLATE OPENING (LIMITING-PLATE OPENING FOR VAPOR DEPOSITION FLOW)
72 LIMITING PLATE (SECOND LIMITING PLATE)
73 LIMITING-PLATE OPENING (LIMITING-PLATE OPENING FOR GAS)
80 LIMITING PLATE UNIT (THIRD LIMITING PLATE UNIT)
81 OPENING (LIMITING-PLATE OPENING FOR VAPOR DEPOSITION FLOW)
82 LIMITING PLATE (THIRD LIMITING PLATE)
83 GAP (LIMITING-PLATE OPENING FOR GAS)
90 LIMITING PLATE UNIT (SECOND LIMITING PLATE UNIT, GAS INJECTION UNIT)
91 LIMITING-PLATE OPENING (LIMITING-PLATE OPENING FOR VAPOR DEPOSITION FLOW)
92 LIMITING PLATE (SECOND LIMITING PLATE)
100 VAPOR DEPOSITION DEVICE
101 FILM FORMING CHAMBER
102 SUBSTRATE HOLDER
103 SUBSTRATE MOVING DEVICE
104 VAPOR-DEPOSITION-UNIT MOVING DEVICE
110 EVACUATION MECHANISM
111 EVACUATION TUBE
112 EVACUATION DEVICE
120 LIMITING PLATE UNIT (THIRD LIMITING PLATE UNIT, GAS INJECTION UNIT)
121 LIMITING-PLATE OPENING (LIMITING-PLATE OPENING FOR VAPOR DEPOSITION FLOW)
122 LIMITING PLATE (THIRD LIMITING PLATE)
200 FILM FORMING TARGET SUBSTRATE
201 FILM FORMING TARGET SURFACE
202 FILM FORMING TARGET REGION
203, 203R, 203G, 203B TARGET FILM FORMING PATTERN REGION
204 NON-FILM FORMING REGION
205 PENETRATION PORT (OPENING PORTION)
300, 300R, 300G, 300B VAPOR DEPOSITION FILM
301 VAPOR DEPOSITION PARTICLE
302 VAPOR DEPOSITION FILM
400 ORGANIC EL DISPLAY DEVICE
401 PIXEL
402 SUB PIXEL
501 GAS WALL
601 VAPOR DEPOSITION SOURCE
601 VAPOR DEPOSITION PARTICLE
602 VAPOR-DEPOSITION SOURCE OPENING
611 VAPOR DEPOSITION MASK
612 MASK OPENING
621 LIMITING PLATE
622 LIMITING-PLATE OPENING

1. A vapor deposition device forming a vapor deposition film including a plurality of predetermined patterns, in a plurality of film forming target regions of a film forming target substrate including the plurality of film forming target regions in a first direction, the predetermined patterns being arranged in the first direction, the device comprising:
a vapor deposition source including a plurality of vapor-deposition source openings for emitting vapor deposition particles;
a vapor deposition mask including a mask opening region to include a plurality of mask openings arranged in the first direction, the mask opening region facing each of the plurality of film forming target regions, the mask openings corresponding to the patterns of the vapor deposition film;
a first limiting plate unit provided between the vapor deposition source and the vapor deposition mask, the first limiting plate unit including a plurality of first limiting plates to be separated from each other in the first direction, the first limiting plate unit including a first limiting-plate opening, the first limiting-plate opening causing the vapor deposition particles to pass therethrough, the first limiting-plate opening being provided between the first limiting plates adjacent to each other and corresponding to each of the film forming target regions; and
a gas supply mechanism configured to form a gas wall at a portion between the vapor deposition mask and the first limiting plate unit, wherein
the gas wall is formed in a non-opening region positioned between first limiting-plate openings of the first limiting plate unit and positioned between mask opening regions of the vapor deposition mask, in the first direction in plan view, the first limiting-plate openings being adjacent to each other, the mask opening regions being adjacent to each other.

2. The vapor deposition device according to claim 1, wherein
a gas injection port is provided in each of the first limiting plates, the gas injection port causing a gas for forming the gas wall to be injected toward the non-opening region in the vapor deposition mask.

3. The vapor deposition device according to claim 2, further comprising
a second limiting plate unit provided between the first limiting plate unit and the vapor deposition mask, the second limiting plate unit including a plurality of second limiting plates, the second limiting plates facing the first limiting plates and to be separated from each other in plan view, wherein
each of the second limiting plates includes a plurality of second limiting plates provided for one first limiting plate, in the first direction, and interposing the gas injection port in plan view.

4. The vapor deposition device according to claim 1, wherein
the gas supply mechanism includes a gas injection unit, the gas injection unit including a plurality of gas injection ports, each of the gas injection ports causing a gas for forming the gas wall to be injected, and
the gas injection unit is provided between the vapor deposition mask and the first limiting plate unit.

5. The vapor deposition device according to claim 4, wherein
the gas injection unit includes a second limiting plate unit provided between the first limiting plate unit and the vapor deposition mask to be adjacent to the first limiting plate unit, the second limiting plate unit including a plurality of second limiting plates, the second limiting plates facing the first limiting plates and being separated from each other in plan view,
the gas injection ports are provided in the second limiting plates, and
the gas injection port causes the gas for forming the gas wall to be injected toward the non-opening region in the vapor deposition mask.

6. The vapor deposition device according to claim 2, further comprising
a third limiting plate unit provided between the first limiting plate unit and the vapor deposition mask to be adjacent to the vapor deposition mask, the third limiting plate unit including a plurality of third limiting plates, the third limiting plates facing the non-opening region between the mask opening regions in the vapor deposition mask and being separated from each other, wherein
each of the third limiting plates includes a plurality of third limiting plates provided for one non-opening region, in the first direction, and interposing the gas wall in plan view.

7. The vapor deposition device according to claim 1, further comprising
an evacuation device, wherein
an inlet port is provided in the vapor deposition mask, the inlet port being connected to the evacuation device and sucking a gas for forming the gas wall.

8. The vapor deposition device according to claim 1, wherein
an opening portion is provided in each of the vapor deposition mask and the film forming target substrate, the opening portion causing a gas for forming the gas wall to pass therethrough, and
the gas wall is formed to penetrate the vapor deposition mask and the film forming target substrate.

9. The vapor deposition device according to claim 4, wherein
the gas injection unit includes a third limiting plate unit provided between the first limiting plate unit and the vapor deposition mask to be adjacent to the vapor deposition mask, the third limiting plate unit including a plurality of third limiting plates, the third limiting plates facing the non-opening region in the vapor deposition mask and being separated from each other in plan view,
the gas injection ports are provided in the third limiting plates, and
the gas injection port causes the gas for forming the gas wall to be injected toward the first limiting plate.

10. The vapor deposition device according to claim 6, wherein
the third limiting plate unit functions as a mask frame to fix an edge of the vapor deposition mask.

11. The vapor deposition device according to claim 1, wherein
a gas injection port is provided in the non-opening region between the mask opening regions in the vapor deposition mask, the gas injection port causing a gas for forming the gas wall to be injected toward the first limiting plate.

12. The vapor deposition device according to claim 9, further comprising
an evacuation device, wherein
an inlet port is provided in the first limiting plate, the inlet port being connected to the evacuation device and sucking the gas for forming the gas wall.

13. The vapor deposition device according to claim 2, wherein
the gas injection port includes a plurality of gas injection ports, the gas injection ports being provided for one first limiting plate in the first direction to cause a plurality of gas walls to be formed.

14. The vapor deposition device according to claim 2, wherein
the gas injection port is extended along the first limiting-plate opening in a second direction perpendicular to the first direction in plan view, and is in a shape, the width of an opening, of the shape, in the first direction being the widest at a portion adjacent to each of the vapor-deposition source openings in the first direction and being tapered toward edges in the second direction in plan view.

15. The vapor deposition device according to claim 2, wherein
in plan view, disposition density of gas injection ports is relatively high in a region being relatively close to each of the vapor-deposition source openings,
the disposition density of the gas injection ports is relatively low in a region being relatively far from the vapor-deposition source opening, and
the total opening width of the gas injection ports in the first direction in the region being relatively close to the vapor-deposition source opening is wider than the total opening width of the gas injection ports in the first direction in the region being relatively far from the vapor-deposition source opening.

16. A vapor deposition method of forming a vapor deposition film including a plurality of predetermined patterns, in a plurality of film forming target regions of a film forming target substrate including the plurality of film forming target regions in a first direction, the predetermined patterns being arranged in the first direction, the method comprising:
disposing a first limiting plate unit between a vapor deposition source and a vapor deposition mask, the vapor deposition source including a plurality of vapor-deposition source openings for emitting vapor deposition particles, the vapor deposition mask including a mask opening region provided to include a plurality of mask openings arranged in the first direction, the mask opening region being provided to face each of the plurality of film forming target regions, the mask openings corresponding to the patterns of the vapor deposition film, the first limiting plate unit including a plurality of first limiting plates provided to be separated from each other in the first direction, the first limiting plate unit including a first limiting-plate opening provided between the first limiting plates adjacent to each other, the first limiting-plate opening causing the vapor deposition particles to pass therethrough and corresponding to each of the film forming target regions; and
emitting the vapor deposition particles from the vapor deposition source and forming the vapor deposition film while forming a gas wall in a non-opening region by a gas supply mechanism, the non-opening region being a portion between the vapor deposition mask and the first limiting plate unit and being positioned between first limiting-plate openings of the first limiting plate unit, the first limiting-plate openings being adjacent to each other, the non-opening region being positioned between mask opening regions of the vapor deposition mask, the mask opening regions being adjacent to each other, in the first direction in plan view.
